(19) United States
(12) Patent Application Publication
(10) Pub. No.: US 2013/0337586 A1
(43) Pub. Date: Dec. 19, 2013

(54) POLISHING METHOD

(71) Applicant: EBARA CORPORATION, Tokyo (JP)

(72) Inventors: TAKESHI IIZUMI, Tokyo (JP); KATSUHIDE WATANABE, Tokyo (JP); YOICHI KOBAYASHI, Tokyo (JP)

(21) Appl. No.: 13/918,372

(22) Filed: Jun. 14, 2013

(30) Foreign Application Priority Data
Jun. 15, 2012 (JP) 2012-135781

(51) Int. Cl. H01L 21/66

(52) U.S. Cl. CPC H01L 22/10; H01L 22/14
USPC 438/16; 438/14; 438/17

(57) ABSTRACT

A method of polishing a substrate includes: performing a first polishing process of bringing the substrate into sliding contact with a polishing pad on a first polishing table to polish a metal film; performing a second polishing process of bringing the substrate into sliding contact with a polishing pad on a second polishing table to polish the metal film until a conductive film is exposed; performing a third polishing process of bringing the substrate into sliding contact with a polishing pad on a third polishing table to polish at least the conductive film; and performing a fourth polishing process of bringing the substrate into sliding contact with a polishing pad on a fourth polishing table to polish at least a dielectric film.

### CROSS REFERENCE TO RELATED APPLICATION

This document claims priority to Japanese Patent Application No. 2012-135781, filed Jun. 15, 2012, the entire contents of which are hereby incorporated by reference.

### BACKGROUND OF THE INVENTION

1. Field of the Invention

The present invention relates to a method of polishing a substrate, such as a wafer, and more particularly to a method of polishing the substrate using multiple polishing tables.

2. Description of the Related Art

Semiconductor devices are expected to become finer and finer in the future. In order to realize such a fine structure, a polishing apparatus, which is typified by a CMP apparatus, is required to have a more precise processing controllability and a high polishing performance. Specifically, a more accurate remaining film control (i.e., more accurate detection of a polishing end point) and improved polishing results (i.e., less defects and high planarity of polished surface) are required. In addition, a higher productivity (i.e., throughput) is also required.

It is expected that, in the near future, there will be a transition of a wafer size from 300 mm in diameter, which is mainstream as of now, to 450 mm in diameter. Because a 450-mm wafer has a larger area, a longer polishing time may cause an increase in polishing temperature and deposition of by-products on a polishing pad, resulting in a decrease in a polishing performance. Therefore, the polishing apparatus for polishing the 450-mm wafer is required to satisfy rigorous demands including both the polishing performance and the productivity.

In the present polishing apparatus, so-called “rework”, which is re-polishing of the wafer, may be performed in order to improve the polishing accuracy. This re-polishing is a process of transporting the wafer, which has been polished in the polishing apparatus, to an external film thickness measuring device, measuring a film thickness of the polished wafer by the film thickness measuring device, and polishing the wafer again in order to achieve a target film thickness. Such re-polishing is effective at realizing an accurate film thickness, but on the other hand re-polishing could lower the productivity.

### SUMMARY OF THE INVENTION

The present invention has been made for solving the above drawback. It is therefore an object of the present invention to provide a polishing method capable of improving a performance of polishing a substrate, such as a wafer, improving an accuracy of a polishing end point detection, and increasing a throughput.

A first embodiment of the present invention is a method of polishing a substrate having a dielectric film, a conductive film formed on the dielectric film, and a metal film formed on the conductive film. The method includes: performing a first polishing process of bringing the substrate into sliding contact with a polishing pad on a first polishing table to polish the metal film; performing a second polishing process of bringing the substrate into sliding contact with a polishing pad on a second polishing table to polish the metal film until the conductive film is exposed; performing a third polishing process of bringing the substrate into sliding contact with a polishing pad on a third polishing table to polish at least the conductive film; and performing a fourth polishing process of bringing the substrate into sliding contact with a polishing pad on a fourth polishing table to polish at least the dielectric film.

In a preferred aspect of the embodiment, a first processing time which is a sum of a polishing time of the first polishing process and a time of a first preparing process performed before and/or after the first polishing process is equal to a second processing time which is a sum of a polishing time of the second polishing process and a time of a second preparing process performed before and/or after the second polishing process.

In a preferred aspect of the embodiment, each of the first preparing process and the second preparing process includes at least one of a transporting process of the substrate, a dressing process of the polishing pad, and a water-polishing process in which the substrate is polished while water is supplied onto the polishing pad.

In a preferred aspect of the embodiment, the third polishing process comprises a process of bringing the substrate into sliding contact with the polishing pad on the third polishing table to polish the conductive film until a thickness of the conductive film reaches a predetermined target value; and the fourth polishing process comprises a process of bringing the substrate into sliding contact with the polishing pad on the fourth polishing table to polish the conductive film until the dielectric film is exposed and further polish the dielectric film until a thickness of the dielectric film reaches a predetermined target value.

In a preferred aspect of the embodiment, the third polishing process is performed for a predetermined polishing time and the fourth polishing process is performed for a predetermined polishing time.

In a preferred aspect of the embodiment, the predetermined polishing time of the third polishing process is equal to the predetermined polishing time of the fourth polishing process.

In a preferred aspect of the embodiment, a polishing end point of at least one of the third polishing process and the fourth polishing process is detected with use of a film thickness sensor disposed in the third polishing table and/or the fourth polishing table.

In a preferred aspect of the embodiment, a polishing end point of the third polishing process is determined based on a film thickness signal from an eddy current film thickness sensor disposed in the third polishing table.

In a preferred aspect of the embodiment, a polishing end point of the fourth polishing process is determined based on a film thickness signal from an optical film thickness sensor disposed in the fourth polishing table.

In a preferred aspect of the embodiment, a third processing time which is a sum of a polishing time of the third polishing process and a time of a third preparing process performed before and/or after the third polishing process is equal to a fourth processing time which is a sum of a polishing time of the fourth polishing process and a time of a fourth preparing process performed before and/or after the fourth polishing process.

In a preferred aspect of the embodiment, the predetermined target value of the thickness of the conductive film is adjusted such that the third processing time is equal to the fourth processing time.

In a preferred aspect of the embodiment, each of the third preparing process and the fourth preparing process includes at least one of a transporting process of the substrate, a dressing process of the polishing pad, and a water-polishing process in which the substrate is polished while water is supplied onto the polishing pad.

In a preferred aspect of the embodiment, the third polishing process comprises a process of bringing the substrate into sliding contact with the polishing pad on the third polishing table to polish the conductive film until the dielectric film is exposed; and the fourth polishing process comprises a process of bringing the substrate into sliding contact with the polishing pad on the fourth polishing table to polish the dielectric film until a thickness of the dielectric film reaches a predetermined target value.

In a preferred aspect of the embodiment, the third polishing process is performed while supplying a polishing liquid onto the polishing pad on the third polishing table, the polishing liquid having properties of relatively higher polishing rate of the conductive film than polishing rate of the dielectric film.

In a preferred aspect of the embodiment, a polishing end point of at least one of the third polishing process and the fourth polishing process is detected with use of a film thickness sensor disposed in the third polishing table and/or the fourth polishing table.

In a preferred aspect of the embodiment, a polishing end point of the third polishing process is determined based on a film thickness signal from an eddy current film thickness sensor disposed in the third polishing table.

In a preferred aspect of the embodiment, a polishing end point of the fourth polishing process is determined based on a film thickness signal from an optical film thickness sensor disposed in the fourth polishing table.

In a preferred aspect of the embodiment, a polishing end point of the third polishing process is determined based on a change in torque current of a table motor for rotating the third polishing table.

In a preferred aspect of the embodiment, the method further includes: prior to the fourth polishing process, performing a water polishing process of polishing the substrate while supplying water onto the polishing pad on the fourth polishing table; obtaining an initial film thickness signal of the dielectric film when the water polishing process is performed; producing an initial film thickness index value from the initial film thickness signal; calculating a target removal amount of the dielectric film from the initial film thickness index value and the predetermined target value of the thickness of the dielectric film; and terminating the fourth polishing process when a removal amount of the dielectric film has reached the target removal amount.

In a preferred aspect of the embodiment, the method further includes: prior to the fourth polishing process, performing a first water polishing process of polishing the substrate while supplying water onto the polishing pad on the fourth polishing table; obtaining an initial film thickness signal of the dielectric film by an optical film thickness sensor disposed in the fourth polishing table when the first water polishing process is performed; after the fourth polishing process, performing a second water polishing process of polishing the substrate while supplying water onto the polishing pad on the fourth polishing table; obtaining an end point film thickness signal of the dielectric film by the optical film thickness sensor when the second water polishing process is performed; calculating a removal amount of the dielectric film from a difference between the initial film thickness signal and the end point film thickness signal; and determining whether or not the thickness of the dielectric film has reached the predetermined target value, based on the calculated removal amount, an initial thickness of the dielectric film, and the predetermined target value of the thickness of the dielectric film.

In a preferred aspect of the embodiment, the method further includes: if the thickness of the dielectric film has not reached the predetermined target value, calculating an additional polishing time for achieving the predetermined target value; and polishing the substrate again for the additional polishing time while supplying a polishing liquid onto the polishing pad.

In a preferred aspect of the embodiment, the method further includes: prior to the fourth polishing process, obtaining an initial film thickness signal of the dielectric film by an optical film thickness sensor disposed beside the fourth polishing table; after the fourth polishing process, obtaining an end point film thickness signal of the dielectric film by the optical film thickness sensor, calculating a removal amount of the dielectric film from a difference between the initial film thickness signal and the end point film thickness signal; and determining whether or not the thickness of the dielectric film has reached the predetermined target value, based on the calculated removal amount, an initial thickness of the dielectric film, and the predetermined target value of the thickness of the dielectric film.

In a preferred aspect of the embodiment, the method further includes: if the thickness of the dielectric film has not reached the predetermined target value, calculating an additional polishing time for achieving the predetermined target value; and polishing the substrate again for the additional polishing time by bringing the substrate into sliding contact with the polishing pad on the fourth polishing table.

In a preferred aspect of the embodiment, the method further includes: prior to the fourth polishing process, obtaining an initial film thickness signal of the dielectric film by a first optical film thickness sensor disposed beside the fourth polishing table; after the fourth polishing process, performing a water polishing process of polishing the substrate while supplying water onto the polishing pad on the fourth polishing table; when performing the water polishing process, obtaining an end point film thickness signal of the dielectric film by a second optical film thickness sensor disposed in the fourth polishing table; calculating a removal amount of the dielectric film from a difference between the initial film thickness signal and the end point film thickness signal; and determining whether or not the thickness of the dielectric film has reached the predetermined target value, based on the calculated removal amount, an initial thickness of the dielectric film, and the predetermined target value of the thickness of the dielectric film.

In a preferred aspect of the embodiment, the method further includes: if the thickness of the dielectric film has not reached the predetermined target value, calculating an additional polishing time for achieving the predetermined target value; and polishing the substrate again for the additional polishing time while supplying a polishing liquid onto the polishing pad.

In a preferred aspect of the embodiment, the third polishing process comprises a process of bringing the substrate into sliding contact with the polishing pad on the third polishing table to polish the conductive film until the dielectric film is exposed and further polish the dielectric film until a thickness of the dielectric film reaches a predetermined first target value; and the fourth polishing process comprises a process of bringing the substrate into sliding contact with the polishing pad on the fourth polishing table to polish the dielectric film until the thickness of the dielectric film reaches a predetermined second target value.

In a preferred aspect of the embodiment, the method further includes: prior to the fourth polishing process, performing a water polishing process of polishing the substrate while supplying water onto the polishing pad on the fourth polishing table; obtaining a film thickness signal of the dielectric film to be polished when the water polishing process is performed; producing a film thickness index value from the film thickness signal; calculating a target removal amount of the dielectric film from the film thickness index value and the predetermined second target value of the thickness of the dielectric film; calculating a polishing time for achieving the target removal amount; and performing the fourth polishing process for the calculated polishing time.

In a preferred aspect of the embodiment, the method further includes: prior to the fourth polishing process, performing a water polishing process of polishing the substrate while supplying water onto the polishing pad on the fourth polishing table; obtaining a film thickness signal of the dielectric film to be polished when the water polishing process is performed; producing a film thickness index value from the film thickness signal; calculating a target removal amount of the dielectric film from the film thickness index value and the predetermined second target value of the thickness of the dielectric film; and terminating the fourth polishing process when a removal amount of the dielectric film has reached the target removal amount.

In a preferred aspect of the embodiment, the third polishing process is performed for a predetermined polishing time and the fourth polishing process is performed for a predetermined polishing time.

In a preferred aspect of the embodiment, the predetermined polishing time of the third polishing process is equal to the predetermined polishing time of the fourth polishing process.

In a preferred aspect of the embodiment, a polishing end point of at least one of the third polishing process and the fourth polishing process is detected with use of a film thickness sensor disposed in the third polishing table and/or the fourth polishing table.

In a preferred aspect of the embodiment, a point of time when the dielectric film is exposed in the third polishing process is determined based on a film thickness signal from an eddy current film thickness sensor disposed in the third polishing table.

In a preferred aspect of the embodiment, a polishing end point of the third polishing process is determined based on a film thickness signal from an optical film thickness sensor disposed in the third polishing table.

In a preferred aspect of the embodiment, a point of time when the dielectric film is exposed in the third polishing process is determined based on a film thickness signal from an eddy current film thickness sensor disposed in the third polishing table, and a polishing end point of the third polishing process is determined based on a film thickness signal from an optical film thickness sensor disposed in the third polishing table.

In a preferred aspect of the embodiment, a polishing end point of the fourth polishing process is determined based on a film thickness signal from an optical film thickness sensor disposed in the fourth polishing table.

Another embodiment of the present invention is a method of polishing a substrate having a dielectric film, a conductive film formed on the dielectric film, and a metal film formed on the conductive film. The method includes: performing a first polishing process of bringing the substrate into sliding contact with a polishing pad on a first polishing table to polish the metal film until a thickness of the metal film reaches a predetermined target value; and performing a second polishing process of bringing the substrate into sliding contact with a polishing pad on a second polishing table to polish the metal film until the conductive film is exposed, a first processing time which is a sum of a polishing time of the first polishing process and a time of a first preparing process performed before and/or after the first polishing process being equal to a second processing time which is a sum of a polishing time of the second polishing process and a time of a second preparing process performed before and/or after the second polishing process.

In a preferred aspect of the embodiment, each of the first preparing process and the second preparing process includes at least one of a transporting process of the substrate, a dressing process of the polishing pad, and a water-polishing process in which the substrate is polished while water is supplied onto the polishing pad.

Still another embodiment of the present invention is a method of polishing a substrate having a dielectric film, a conductive film formed on the dielectric film, and a metal film formed on the conductive film. The method includes: bringing the substrate into sliding contact with a polishing pad attached to one of two polishing tables to polish at least the conductive film; and bringing the substrate into sliding contact with a polishing pad attached to the other of the two polishing tables to polish at least the dielectric film.

Since the four polishing tables are used in accordance with the polishing processes, a polishing time per one polishing table is reduced. Therefore, an increase in a polishing temperature and deposition of by-products are prevented. As a result, substrate defects are reduced, and flatness of the substrate surface is improved. Further, optimum polishing conditions (e.g., polishing liquid, polishing pressure, rotational speed of the polishing table) and an optimum polishing end point detection method can be used in each polishing table in accordance with the type of film to be polished. Therefore, polishing result, such as uniformity of polished film thickness, so called within wafer non-uniformity, can be improved and an accuracy of the polishing endpoint detection is increased. Furthermore, as a result of improved accuracy of the polishing end point detection, the rework (i.e., re-polishing of the substrate) can be eliminated or the number of reworks can be reduced. Therefore, a throughput of wafer polishing can be improved.

### BRIEF DESCRIPTION OF THE DRAWINGS

FIG. 1 is a view showing a polishing apparatus which can perform an embodiment of a polishing method;

FIG. 2 is a perspective view schematically showing a first polishing unit;

FIG. 3 is a cross-sectional view showing an example of a multilayer structure forming interconnects;

FIGS. 4A and 4B are diagrams illustrating a conventional polishing method;

FIGS. 5A through 5D are diagrams illustrating an embodiment of the polishing method;

FIGS. 6A through 6D are diagrams illustrating another embodiment of the polishing method;

FIGS. 7A through 7D are diagrams illustrating still another embodiment of the polishing method;

FIGS. 8A through 8D are diagrams illustrating still another embodiment of the polishing method;

FIG. 9 is a schematic cross-sectional view showing a polishing unit having an eddy current type film thickness sensor and an optical-type film thickness sensor;

FIG. 10 is a schematic view illustrating a principle of the optical film thickness sensor;

FIG. 11 is a plan view showing a positional relationship between the wafer and a polishing table;

FIG. 12 is a diagram showing a spectrum created by an operation controller;

FIG. 13 is a diagram illustrating a process of determining a current film thickness from a comparison of the created spectrum with a plurality of reference spectra;

FIG. 14 is a schematic view showing two spectra corresponding to a film thickness difference Δα;

FIG. 15A is a schematic cross-sectional view showing a polishing unit including the optical film thickness sensor arranged beside the polishing table;

FIG. 15B is a schematic cross-sectional view showing the polishing unit including the optical film thickness sensor arranged beside the polishing table;

FIG. 16 is a diagram illustrating a principle of an eddy current film thickness sensor;

FIG. 17 is a diagram showing a graph drawn by plotting coordinates X and Y, which change with a film thickness, on a XY coordinate system;

FIG. 18 shows a graph obtained by rotating the graph in FIG. 17 through 90 degrees in a counterclockwise direction and further translating the resulting graph;

FIG. 19 is a graph showing arcuate paths of the coordinates X and Y that change in accordance with a distance between a coil and a wafer; and

FIG. 20 is a graph showing an angle θ that varies in accordance with polishing time.

### DETAILED DESCRIPTION

Embodiments will be described with reference to the drawings.

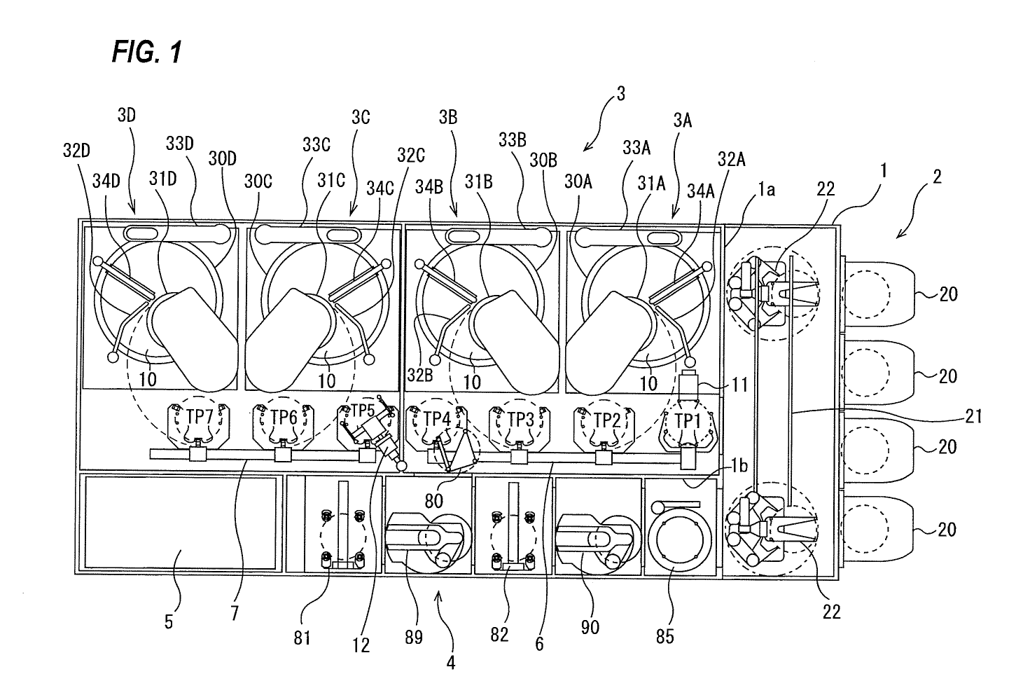

FIG. 1 is a view showing a polishing apparatus capable of performing an embodiment of a polishing method. As shown in FIG. 1, the polishing apparatus has a housing 1 in a rectangular shape. An interior space of the housing 1 is partitioned by partitions 1a and 1b into a load-unload section 2, a polishing section 3, and a cleaning section 4. The polishing apparatus includes an operation controller 5 configured to control wafer processing operations.

The load-unload section 2 has front load sections 20 on which wafer cassettes are placed, respectively. A plurality of wafers (substrates) are stored in each wafer cassette. The load-unload section 2 has a moving mechanism 21 extending along an arrangement direction of the front load sections 20. Two transfer robots (loaders) 22 are provided on the moving mechanism 21, so that the transfer robots 22 can move along the arrangement direction of the front load sections 20. Each transfer robot 22 is able to access the wafer cassettes mounted to the front load sections 20.

The polishing section 3 is an area where a wafer is polished. This polishing section 3 includes a first polishing unit 3A, a second polishing unit 3B, a third polishing unit 3C, and a fourth polishing unit 3D. As shown in FIG. 1, the first polishing unit 3A includes a first polishing table 30A supporting a polishing pad 10 having a polishing surface, a first top ring 31A for holding a wafer and pressing the wafer against the polishing pad 10 on the polishing table 30A so as to polish the wafer, a first polishing liquid supply mechanism 32A for supplying a polishing liquid (e.g., slurry) and a dressing liquid (e.g., pure water) onto the polishing pad 10, a first dresser 33A for dressing the polishing surface of the polishing pad 10, and a first atomizer 34A for ejecting a liquid (e.g., pure water) or a mixture of a liquid (e.g., pure water) and a gas (e.g., nitrogen gas) in an atomized state onto the polishing surface of the polishing pad 10.

Similarly, the second polishing unit 3B includes a second polishing table 30B supporting a polishing pad 10, a second top ring 31B, a second polishing liquid supply mechanism 32B, a second dresser 33B, and a second atomizer 34B. The third polishing unit 3C includes a third polishing table 30C supporting a polishing pad 10, a third top ring 31C, a third polishing liquid supply mechanism 32C, a third dresser 33C, and a third atomizer 34C. The fourth polishing unit 3D includes a fourth polishing table 30D supporting a polishing pad 10, a fourth top ring 31D, a fourth polishing liquid supply mechanism 32D, a fourth dresser 33D, and a fourth atomizer 34D.

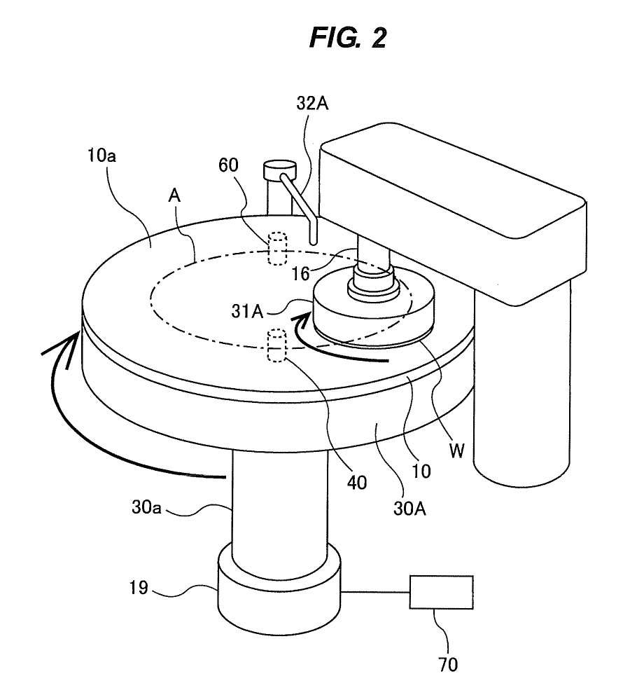

The first polishing unit 3A, the second polishing unit 3B, the third polishing unit 3C, and the fourth polishing unit 3D have the same configuration. Therefore, the first polishing unit 3A will be described below with reference to FIG. 2. FIG. 2 is a perspective view schematically showing the first polishing unit 3A. In FIG. 2, the dresser 33A and the atomizer 34A are omitted.

The polishing table 30A is coupled to a table motor 19 through a table shaft 30a, so that the polishing table 30A is rotated by the table motor 19 in a direction indicated by arrow. The table motor 19 is provided below the polishing table 30A. The polishing pad 10 is attached to an upper surface of the polishing table 30A. The polishing pad 10 has an upper surface 12a, which provides a polishing surface for polishing the wafer W.

The top ring 31A is secured to a lower end of the top ring shaft 16. The top ring 31A is configured to hold the wafer W on its lower surface by vacuum suction. The top ring shaft 16 is elevated and lowered by an elevating mechanism (not shown in the drawing).

An optical film thickness sensor 40 and an eddy current film thickness sensor 60 each for obtaining film thickness signal that varies in accordance with a film thickness of the wafer W are arranged in the polishing table 30A. These film thickness sensors 40 and 60 are rotated in unison with the polishing table 30A as illustrated by arrow A and obtain the film thickness signals of the wafer W held by the top ring 31A. The optical film thickness sensor 40 and the eddy current film thickness sensor 60 are coupled to the operation controller 5 shown in FIG. 1 so that the film thickness signals obtained are transmitted to the operation controller 5.

Further, a torque current measuring device 70 is provided for measuring an input current (i.e., a torque current) of the table motor 19 that rotates the polishing table 30A.

A value of the torque current measured by the torque current measuring device 70 is sent to the operation controller 5, which monitors the value of the torque current during polishing of the wafer W.

The wafer W is polished as follows. The top ring 31A and the polishing table 30A are rotated, while the polishing liquid (i.e., the slurry) is supplied onto the polishing pad 10 from the polishing liquid supply mechanism 32A. In this state, the top ring 31A, holding the wafer W on its lower surface, is lowered by the top ring shaft 16 and presses the wafer W against the polishing surface 10a of the polishing pad 10. The surface of the wafer W is polished by a mechanical action of abrasive grains contained in the polishing liquid and a chemical action of the polishing liquid. After polishing of the wafer W, dressing (or conditioning) of the polishing surface 10a is performed by the dresser 33A. Further, high-pressure fluid is supplied from the atomizer 34A onto the polishing surface 10a to remove polishing debris and the abrasive grains from the polishing surface 10a.

As shown in FIG. 1, a first linear transporter 6 is arranged adjacent to the first polishing unit 3A and the second polishing unit 3B. This first linear transporter 6 is configured to transport the wafer between four transfer positions (i.e., a first transfer position TP1, a second transfer position TP2, a third transfer position TP3, and a fourth transfer position TP4). A second linear transporter 7 is arranged adjacent to the third polishing unit 3C and the fourth polishing unit 3D. This second linear transporter 7 is configured to transport the wafer between three transfer positions (i.e., a fifth transfer position TP5, a sixth transfer position TP6, and a seventh transfer position TP7).

The wafer is transported to the first polishing unit 3A and the second polishing unit 3B by the first linear transporter 6. The top ring 31A of the first polishing unit 3A is moved between a position above the polishing table 30A and the second transfer position TP2 by the swinging motion of the top ring 31A. Therefore, the wafer is transferred to and from the top ring 31A at the second transfer position TP2. Similarly, the top ring 31B of the second polishing unit 3B is moved between a position above the polishing table 30B and the third transfer position TP3, and the wafer is transferred to and from the top ring 31B at the third transfer position TP3. The top ring 31C of the third polishing unit 3C is moved between a position above the polishing table 30C and the sixth transfer position TP6, and the wafer is transferred to and from the top ring 31C at the sixth transfer position TP6. The top ring 31D of the fourth polishing unit 3D is moved between a position above the polishing table 30D and the seventh transfer position TP7, and the wafer is transferred to and from the top ring 31D at the seventh transfer position TP7.

A lifter 11 is provided adjacent to the first transfer position TP1 for receiving the wafer from the transfer robot 22. The wafer is transported from the transfer robot 22 to the first linear transporter 6 via the lifter 11. A shutter (not shown in the drawing) is provided on the partition 1a at a position between the lifter 11 and the transfer robot 22. When the wafer is to be transported, this shutter is opened to allow the transfer robot 22 to deliver the wafer to the lifter 11.

A swing transporter 12 is provided between the first linear transporter 6, the second linear transporter 7, and the cleaning section 4. Transporting of the wafer from the first linear transporter 6 to the second linear transporter 7 is performed by the swing transporter 12. The wafer is transported to the third polishing unit 3C and/or the fourth polishing unit 3D by the second linear transporter 7.

A temporary base 80 for the wafer W is arranged beside the swing transporter 12. This temporary base 80 is mounted on a non-illustrated frame. As shown in FIG. 1, the temporary base 80 is arranged adjacent to the first linear transporter 6 and located between the first linear transporter 6 and the cleaning section 4. The swing transporter 12 is configured to move between the fourth transfer position TP4, the fifth transfer position TP5, and the temporary base 80.

The wafer W, placed on the temporary base 80, is transported to the cleaning section 4 by a first transfer robot 89 of the cleaning section 4. As shown in FIG. 1, the cleaning section 4 includes a first cleaning module 81 and a second cleaning module 82 for cleaning the polished wafer with a cleaning liquid, and a drying module 85 for drying the cleaned wafer. The first transfer robot 89 is configured to transport the wafer from the temporary base 80 to the first cleaning module 81 and further transport the wafer from the first cleaning module 81 to the second cleaning module 82. A second transfer robot 90 is arranged between the second cleaning module 82 and the drying module 85. This second transfer robot 90 is operable to transport the wafer from the second cleaning module 82 to the drying module 85.

The dried wafer is removed from the drying module 85 by the transfer robot 22 and returned to the wafer cassette. In this manner, a sequence of processes including polishing, cleaning, and drying of the wafer is performed.

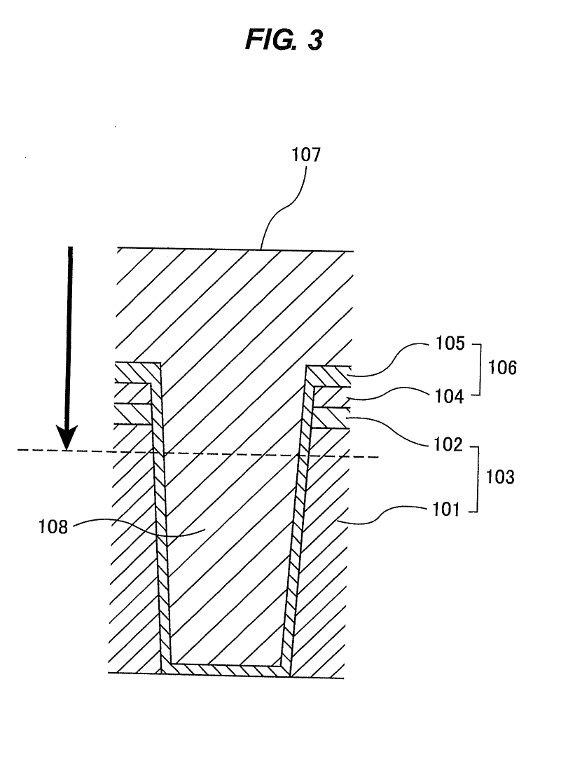

FIG. 3 is a cross-sectional view showing an example of a multilayer structure forming interconnects. As shown in FIG. 3, a first hard mask film 102, e.g., an oxide film of SiO₂ or a nitride film of SiN, is formed on an interlayer dielectric film 101 made of SiO₂ or a low-k material. A second hard mask film 104 made of a metal, such as Ti, TiN, or the like, is formed on the first hard mask film 102. A barrier film 105, which is made of a metal, such as Ta, TaN, or Ru or layers of these metals, is formed so as to cover a trench formed in the interlayer dielectric film 101 and the second hard mask film 104. The interlayer dielectric film 101 and the first hard mask film 102 constitute a dielectric film 103, while the second hard mask film 104 and the barrier film 105 constitute a conductive film 106. Although not shown, in another example of the multilayer structure, the first hard mask film 102 and the second hard mask film 104 may not be provided. In this case, the barrier film 105 constitutes the conductive film, and the interlayer dielectric film 101 constitutes the dielectric film. In still another example, a wafer may not include either one of the first hard mask film 102 or the second hard mask film 104. In this case also, a copper film, a conductive film, and a dielectric film constitute a multilayer structure.

After the barrier film 105 is formed, the wafer is plated with copper, so that the trench is filled with copper and a copper film 107 as a metal film is deposited on the barrier film 105. Thereafter, a chemical mechanical polishing (CMP) process is performed on the wafer to remove unnecessary films, i.e., the copper film 107, the barrier film 105, the second hard mask film 104, and the first hard mask film 102, leaving copper in the trench. This copper remaining in the trench, which is a part of the copper film 107, forms interconnects 108 of a semiconductor device. The CMP process is terminated when the dielectric film 103 reaches a predetermined thickness, i.e., when the interconnects 108 reach a predetermined height, as indicated by a dotted line in FIG. 3.

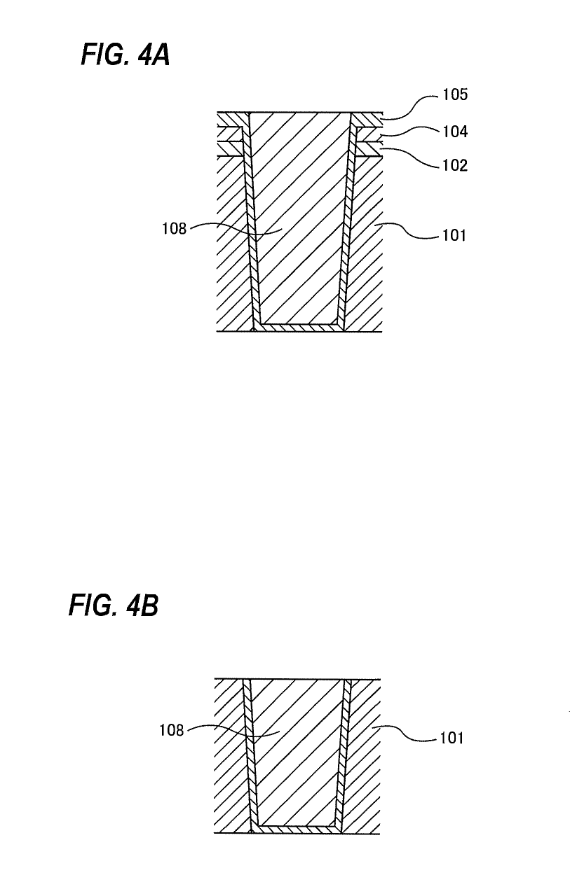

According to a conventional polishing process, a wafer having the above multilayer structure is polished in two stages by the first polishing unit 3A and the second polishing unit 3B, and at the same time, another wafer of the same structure is polished in two stages by the third polishing unit 3C and the fourth polishing unit 3D. The first stage of the two stages is a process of removing the unnecessary copper film 107 until the barrier film 105 is exposed, as shown in FIG. 4A. The second stage is a process of removing the barrier film 105, the second hard mask film 104, and the first hard mask film 102, and then polishing the interlayer dielectric film 101 until the dielectric film 103 reaches a predetermined thickness, i.e., until the interconnects 108 in the trench reach a predetermined height, as shown in FIG. 4B. The first stage is carried out by the first polishing unit 3A and the third polishing unit 3C, and the second stage is carried out by the second polishing unit 3B and the fourth polishing unit 3D. In this manner, the two wafers are concurrently polished by the polishing units 3A and 3B and the polishing units 3C and 3D, respectively.

However, such a conventional polishing process entails a long polishing time per each polishing unit, which may cause defects on wafers or lower the wafer surface planarity due to an increase in the polishing temperature and/or the deposition of by-products on the polishing pads. Thus, in one embodiment, one wafer is polished successively using the four polishing units 3A, 3B, 3C, and 3D.

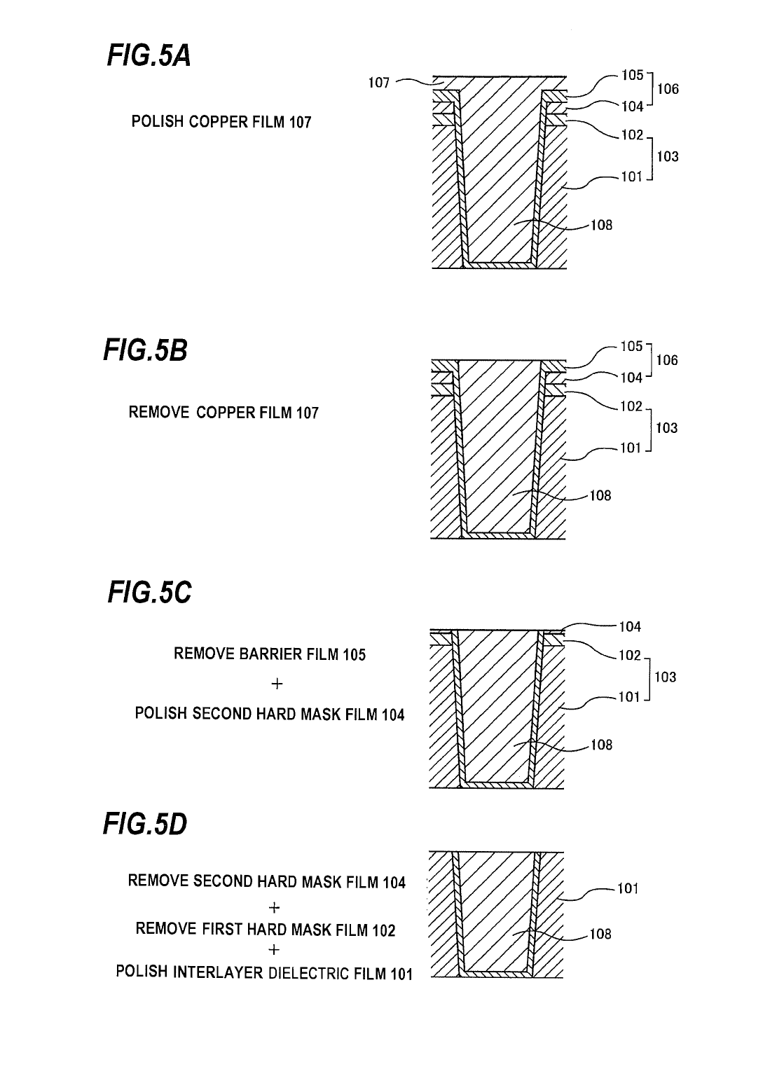

An embodiment of a polishing method will be described below with reference to FIGS. 5A through 5D. As shown in FIG. 5A, in a first polishing process, the copper film 107 is polished by the first polishing unit 3A until the thickness of the copper film 107 reaches a predetermined target value. While the copper film 107 is polished, the eddy current film thickness sensor 60 obtains the film thickness signal of the copper film 107. The operation controller 5 produces a film thickness index value, which directly or indirectly indicates the film thickness of the copper film 107, from the film thickness signal, monitors polishing of the copper film 107 based on the thickness index value, and terminates polishing of the copper film 107 when the film thickness index value reaches a predetermined threshold value, i.e., when the thickness of the copper film 107 reaches the predetermined target value.

The wafer that has been polished in the first polishing unit 3A is transported to the second polishing unit 3B, where a second polishing process is performed. In this second polishing process, the remaining copper film 107 is polished until the barrier film 105 lying underneath the copper film 107 is exposed, as shown in FIG. 5B. A point of time when the barrier film 105 is exposed as a result of removal of the copper film 107 is detected by the operation controller 5 based on the film thickness index value. For example, a point of time when the copper film 107 is removed may be determined from the point of time when the film thickness index value has reached the predetermined threshold value. If the polishing liquid used has properties such that the copper film 107 is polished at a high polishing rate while the barrier film 105 is polished at a low polishing rate, polishing of the wafer does not progress any more once the copper film 107 is removed and the barrier film 105 is exposed. In this case, the film thickness index value becomes unchanged. Therefore, the point of time when the film thickness index value stops changing may be determined to be the point of time when the copper film 107 is removed.

Polishing conditions of the wafer may be changed in the first polishing process and the second polishing process. The polishing conditions may include the type of polishing liquid supplied to the wafer, the polishing pressure applied from the top ring to the wafer, and the rotational speed of the polishing table. For example, in the first polishing process, the wafer may be pressed against the polishing pad 10 at a predetermined first polishing pressure and may be polished at a high polishing rate (which is also called “removal rate”), and in the second polishing process, the wafer may be pressed against the polishing pad 10 at a second polishing pressure which is lower than the first polishing pressure and may be polished at a low polishing rate. Since the first polishing process is carried out under the higher polishing pressure, the polishing time is shortened. Since the second polishing process is carried out under the lower polishing pressure, the polishing end point can be detected accurately, a flatness of the polished wafer surface is improved, and defects on the polished wafer surface are reduced.

As described above, polishing of the copper film 107 is divided into the first polishing process in the first polishing unit 3A and the second polishing process in the second polishing unit 3B. Therefore, the polishing time per each polishing unit can be short, compared with the conventional polishing method in which the copper film 107 is polished by a single polishing unit.

If a total processing time in the first polishing unit 3A (hereinafter referred to as “first processing time”) and a total processing time in the second polishing unit 3B (hereinafter referred to as “second processing time”) are the same as each other, the productivity (throughput) is the highest. Therefore, the first processing time in the first polishing unit 3A and the second processing time in the second polishing unit 3B are preferably the same as each other. The predetermined threshold value of the film thickness index value in the first polishing process (i.e., the target value of the thickness of the copper film 107) may be adjusted so as to equalize the first processing time with the second processing time in polishing of a subsequent wafer. The first processing time is the sum of a time of a first preparing process that is carried out before and/or after the first polishing process and a polishing time of the first polishing process. The second processing time is the sum of a time of a second preparing process that is carried out before and/or after the second polishing process and a polishing time of the second polishing process. Each of the first preparing process and the second preparing process includes at least one of a transporting process of the wafer, a dressing process of the polishing pad 10, and a water-polishing process in which the wafer is polished while water is supplied onto the polishing pad 10.

The wafer that has been polished in the second polishing unit 3B is transported to the third polishing unit 3C where a third polishing process is performed. In the third polishing process, the barrier film 105 and the second hard mask film 104, which constitute the conductive film 106, are polished as shown in FIG. 5C. More specifically, the conductive film 106 is polished until the thickness of the conductive film 106 reaches a predetermined target value. In the example shown in FIG. 5C, the barrier film 105 is removed, and a part of the second hard mask film 104 is removed. In another example of the third polishing process, polishing of the barrier film 105 may be stopped before the second hard mask film 104 is exposed. While the conductive film 106 is polished, the eddy current film thickness sensor 60 obtains the film thickness signal of the conductive film 106. The operation controller 5 produces the film thickness index value, which directly or indirectly indicates the thickness of the conductive film 106, from the film thickness signal, monitors polishing of the conductive film 106 based on the film thickness index value, and terminates polishing of the conductive film 106 when the film thickness index value reaches a predetermined threshold value, i.e., when the thickness of the conductive film 106 reaches the predetermined target value.

The wafer that has been polished in the third polishing unit 3C is transported to the fourth polishing unit 3D where a fourth polishing process is performed. As shown in FIG. 5D, in the fourth polishing process, the conductive film 106 is polished until the dielectric film 103 is exposed and further the exposed dielectric film 103 is polished. Specifically, the remaining conductive film 106 (i.e., only the second hard mask film 104, or the barrier film 105 and the second hard mask film 104) is removed, and subsequently the dielectric film 103 lying underneath the conductive film 106 is polished. The dielectric film 103 is constructed by the first hard mask film 102 and the interlayer dielectric film 101 lying underneath the first hard mask film 102. The dielectric film 103 is polished until its thickness reaches a predetermined target value. Polishing of the dielectric film 103 includes the removal of the first hard mask film 102 and polishing of the interlayer dielectric film 101.

When the remaining conductive film 106 is polished as described above, the eddy current film thickness sensor 60 obtains the film thickness signal of the conductive film 106. The operation controller 5 produces the film thickness index value of the conductive film 106 from the film thickness signal, and detects a point of time when the conductive film 106 is removed (i.e., a point of time when the dielectric film 103 is exposed) based on the film thickness index value. For example, the operation controller 5 can determine the removal point of the conductive film 106 from a point of time when the film thickness index value reaches a predetermined threshold value. Once the conductive film 106 is removed and the dielectric film 103 is exposed, the film thickness index value of the conductive film 106 no longer changes. Therefore, the point of time when the film thickness index value stops changing may be determined to be the point of time when the conductive film 106 is removed.

In this embodiment, the conductive film 106 and the dielectric film 103 are polished successively. When the dielectric film 103 is polished, the film thickness signal of the dielectric film 103 is obtained by the optical film thickness sensor 40. The operation controller 5 produces the film thickness index value, which directly or indirectly indicates the thickness of the dielectric film 103, from the film thickness signal, and terminates polishing of the dielectric film 103 when the film thickness index value reaches a predetermined threshold value, i.e., when the thickness of the dielectric film 103 reaches a predetermined target value. The operation controller 5 may determine the polishing end point of the dielectric film 103 from an initial thickness of the dielectric film 103 (or a presumed initial film thickness if the actual initial thickness of the dielectric film 103 is unknown) and an amount of the dielectric film 103 that has been removed (i.e., a removal amount). Specifically, the operation controller 5 may produce, rather than the film thickness index value, a removal index value which directly or indirectly indicates the removal amount of the dielectric film 103 from the film thickness signal, and may terminate polishing of the dielectric film 103 when the removal index value reaches a predetermined threshold value, i.e., when the removal amount of the dielectric film 103 reaches a predetermined target value. In this case also, the dielectric film 103 can be polished until its thickness reaches the predetermined target value.

The polishing conditions (e.g., the polishing liquid, the polishing pressure, and the rotational speed of the polishing table) of the wafer may be changed in the third polishing process and the fourth polishing process. Further, the polishing conditions may be changed in accordance with the type of film to be polished (the conductive film 106 and the dielectric film 103) while each polishing process is being performed. For example, in the fourth polishing process, the polishing conditions may be changed when the removal of the conductive film 106 is detected based on the film thickness signal from the eddy current film thickness sensor 60.

A total processing time in the third polishing unit 3C (hereinafter referred to as “third processing time”) and a total processing time in the fourth polishing unit 3D (hereinafter referred to as “fourth processing time”) are preferably the same as each other. The predetermined threshold value of the film thickness index value in the third polishing process (i.e., the target value of the thickness of the conductive film 106) may be adjusted so as to equalize the third processing time with the fourth processing time in polishing of a subsequent wafer. The third processing time is the sum of a time of a third preparing process that is carried out before and/or after the third polishing process and a polishing time of the third polishing process. The fourth processing time is the sum of a time of a fourth preparing process that is carried out before and/or after the fourth polishing process and a polishing time of the fourth polishing process. Each of the third preparing process and the fourth preparing process includes at least one of a transporting process of the wafer, a dressing process of the polishing pad 10, and a water-polishing process in which the wafer is polished while water is supplied onto the polishing pad 10.

In this embodiment, the end point of the third polishing process and the end point of the fourth polishing process may be managed with use of polishing times. Specifically, the conductive film 106 may be polished in the third polishing unit 3C for a predetermined polishing time, and the conductive film 106 and the dielectric film 103 may be polished in the fourth polishing unit 3D for a predetermined polishing time. In this case, the film thicknesses or the removal amounts of the conductive film 106 and the dielectric film 103 may not be monitored by the eddy current film thickness sensor 60 and the optical film thickness sensor 40. The above-described predetermined polishing time of the conductive film 106 in the third polishing unit 3C may preferably be the same as the above-described predetermined polishing time of the conductive film 106 and the dielectric film 103 in the fourth polishing unit 3D.

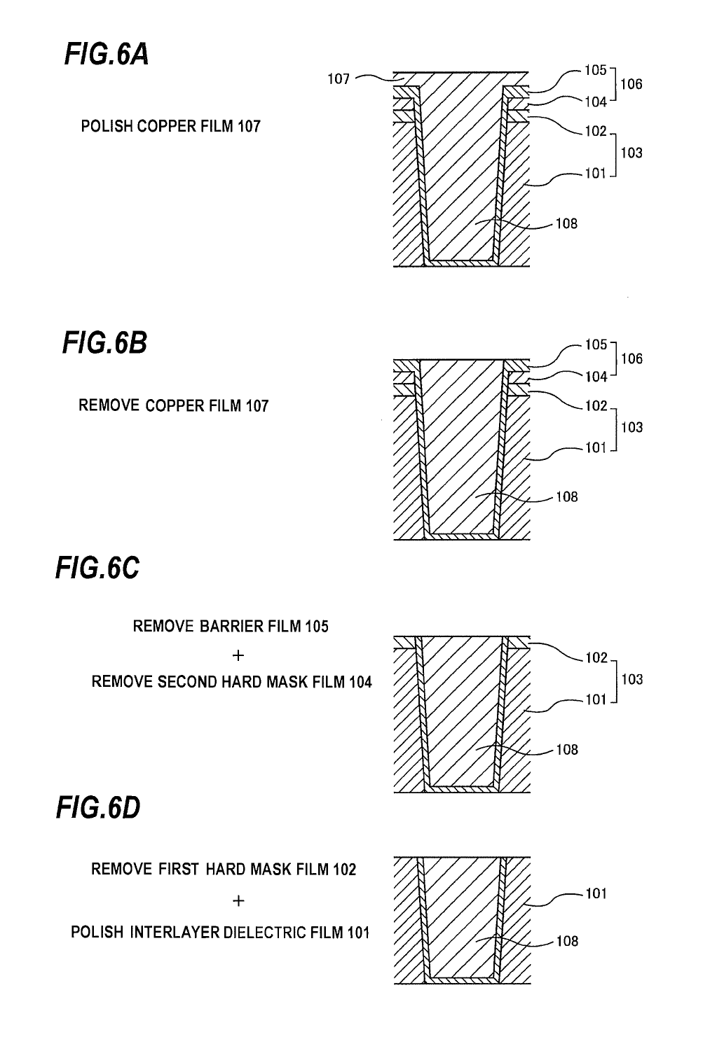

Another embodiment of the polishing method will be described below with reference to FIGS. 6A through 6D. A first polishing process shown in FIG. 6A and a second polishing process shown in FIG. 6B are identical respectively to the first polishing process and the second polishing process according to the above-discussed embodiment shown in FIG. 5A and FIG. 5B, respectively, and their repetitive descriptions are omitted.

The wafer that has been polished in the second polishing unit 3B is transported to the third polishing unit 3C where a third polishing process is performed. In the third polishing process, as shown in FIG. 6C, the barrier film 105 and the second hard mask film 104, which constitute the conductive film 106, are removed. More specifically, the conductive film 106 is polished until the dielectric film 103 lying underneath the conductive film 106 is exposed, i.e., until the first hard mask film 102 is exposed. While the conductive film 106 is polished, the film thickness signal of the conductive film 106 is obtained by the eddy current film thickness sensor 60. The operation controller 5 produces the film thickness index value from the film thickness signal, monitors polishing of the conductive film 106 based on the film thickness index value, and terminates polishing of the wafer when the film thickness index value reaches a predetermined threshold value or when the film thickness index value stops changing, i.e., when the first hard mask film 102 is exposed as a result of removal of the second hard mask film 104 of the conductive film 106.

The polished wafer is then transported from the third polishing unit 3C to the fourth polishing unit 3D where a fourth polishing process is performed. In the fourth polishing process, as shown in FIG. 6D, the dielectric film 103, which is constructed by the first hard mask film 102 and the interlayer dielectric film 101, is polished. Polishing of the dielectric film 103 includes removing of the first hard mask film 102 and polishing of the interlayer dielectric film 101. The dielectric film 103 is polished until its thickness reaches a predetermined target value.

While the dielectric film 103 is polished, the optical film thickness sensor 40 obtains the film thickness signal of the dielectric film 103. The operation controller 5 produces the film thickness index value or the removal index value of the dielectric film 103 from the film thickness signal, and terminates polishing of the dielectric film 103 when the film thickness index value or the removal index value reaches a predetermined threshold value, i.e., when the thickness or the removal amount of the dielectric film 103 reaches a predetermined target value.

In another embodiment, the polishing method may include performing a water polishing process of polishing the wafer while supplying pure water onto the polishing pad 10 on the fourth polishing table 30D prior to the fourth polishing process, obtaining an initial film thickness signal of the dielectric film 103 by the optical film thickness sensor 40 during the water polishing process, producing an initial film thickness index value from the initial film thickness signal by the operation controller 5, calculating a target removal amount of the dielectric film 103 from the initial film thickness index value and a predetermined target value of the thickness of the dielectric film 103, and terminating the fourth polishing process when the removal amount of the dielectric film 103 in the fourth polishing process reaches the target removal amount of the dielectric film 103.

The polishing conditions (e.g., the polishing liquid, the polishing pressure, and the rotational speed of the polishing table) of the wafer may be changed in the third polishing process and the fourth polishing process. For example, in the third polishing process, it is preferable to use a polishing liquid of high selectivity which contains abrasive grains and/or chemical composition capable of increasing the polishing rate of the conductive film 106 while lowering the polishing rate of the dielectric film 103. With use of such a polishing liquid, polishing of the wafer does not substantially progress after the dielectric film 103 is exposed. Therefore, the operation controller 5 is able to detect the polishing end point of the conductive film 106 more accurately, i.e., the point of time when the dielectric film 103 is exposed. Furthermore, since the accuracy of the polishing end point detection is improved, the rework (i.e., re-polishing of the wafer) can be eliminated or the number of reworks can be reduced. Consequently, a throughput of wafer polishing can be improved.

When the polishing liquid of high selectivity is used in the third polishing process, the polishing end point of the conductive film 106 (i.e., the removal point of the dielectric film 103) can be detected based on the torque current of the table motor 19 (see FIG. 2) which rotates the polishing table 30C. During polishing of the wafer, the surface of the wafer is placed in sliding contact with the polishing surface of the polishing pad 10, so that a frictional force is generated between the wafer and the polishing pad 10. This frictional force varies depending on the type of film that forms an exposed surface of the wafer and the type of polishing liquid.

The table motor 19 is controlled so as to rotate the polishing table 30C at a preset constant speed. When the frictional force acting between the wafer and the polishing pad 10 varies, the value of the current (i.e., the torque current) flowing into the table motor 19 varies. More specifically, the larger the frictional force, the larger the torque current is required to induce a greater torque for rotating the polishing table 30C. The smaller the frictional force, the smaller the torque current is required to induce a smaller torque for rotating the polishing table 30C. Therefore, the operation controller 5 is able to detect the polishing end point of the conductive film 106 (i.e., the removal point of the dielectric film 103) from a change in the torque current of the table motor 19. The torque current is measured by the torque current measuring device 70 shown in FIG. 2.

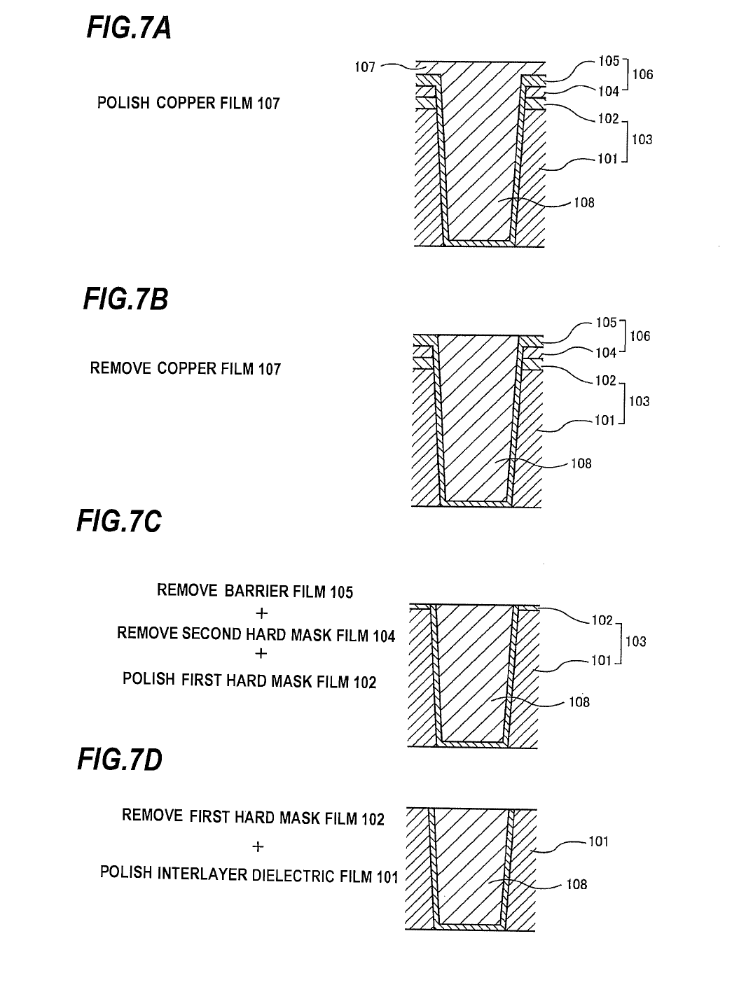

Still another embodiment of polishing method will be described below with reference to FIGS. 7A through 7D. A first polishing process shown in FIG. 7A and a second polishing process shown in FIG. 7B are identical respectively to the first polishing process and the second polishing process according to the above-discussed embodiment shown in FIG. 5A and FIG. 5B, respectively, and their repetitive descriptions are omitted.

The wafer that has been polished in the second polishing unit 3B is transported to the third polishing unit 3C where a third polishing process is performed. In the third polishing process, as shown in FIG. 7C, the conductive film 106 is polished until the dielectric film 103 is exposed, and further the exposed dielectric film 103 is polished. More specifically, the barrier film 105 and the second hard mask film 104, which constitute the conductive film 106, are removed, and the dielectric film 103 lying underneath the conductive film 106 is polished. The dielectric film 103 is polished until its thickness reaches a predetermined first target value. The thickness of the dielectric film 103 may be determined from the removal amount of the dielectric film 103. Polishing of the dielectric film 103 in the third polishing process includes removing of the first hard mask film 102 and polishing of the interlayer dielectric film 101, or only polishing of the first hard mask film 102. FIG. 7C shows an example in which, after the conductive film 106 has been polished, the first hard mask film 102 is polished and the interlayer dielectric film 101 is not polished.

While the conductive film 106 is polished in the third polishing process, the film thickness signal of the conductive film 106 is obtained by the eddy current film thickness sensor 60. The operation controller 5 produces the film thickness index value of the conductive film 106 from the film thickness signal, monitors polishing of the conductive film 106 based on the film thickness index value, and detects a point of time when the film thickness index value reaches a predetermined threshold value or when the film thickness index value stops changing, i.e., a point of time when the dielectric film 103 is exposed as a result of removal of the conductive film 106. In the third polishing process, the conductive film 106 and the dielectric film 103 are successively polished. During polishing of the dielectric film 103, the film thickness signal of the dielectric film 103 is obtained by the optical film thickness sensor 40. The operation controller 5 produces the film thickness index value or the removal index value of the dielectric film 103 from the film thickness signal, and terminates polishing of the dielectric film 103 when the film thickness index value or the removal index value reaches a predetermined first threshold value, i.e., when the thickness or the removal amount of the dielectric film 103 reaches a predetermined first target value.

The wafer that has been polished in the third polishing unit 3C is transported to the fourth polishing unit 3D where a fourth polishing process is performed. In the fourth polishing process, the dielectric film 103 is polished, as shown in FIG. 7D. Polishing of the dielectric film 103 includes removing of the first hard mask film 102 and polishing of the interlayer dielectric film 101 or only polishing of the interlayer dielectric film 101. FIG. 7D shows an example in which the first hard mask film 102 is removed, and subsequently the interlayer dielectric film 101 is polished.

The dielectric film 103 is polished until its thickness reaches a predetermined second target value. The thickness of the dielectric film 103 may be determined from the removal amount of the dielectric film 103. During polishing of the dielectric film 103, the film thickness signal of the dielectric film 103 is obtained by the optical film thickness sensor 40. The operation controller 5 produces the film thickness index value or the removal index value of the dielectric film 103 from the film thickness signal, and terminates polishing of the dielectric film 103 when the film thickness index value or the removal index value reaches a predetermined second threshold value, i.e., when the thickness or the removal amount of the dielectric film 103 reaches a predetermined second target value.

In this embodiment, the end point of the third polishing process and the end point of the fourth polishing process may be managed with use of polishing times. Specifically, the conductive film 106 and the dielectric film 103 may be polished in the third polishing unit 3C for a predetermined polishing time, and the dielectric film 103 may be polished in the fourth polishing unit 3D for a predetermined polishing time. In this case, the film thicknesses or the removal amounts of the conductive film 106 and the dielectric film 103 may not be monitored by the eddy current film thickness sensor 60 and the optical film thickness sensor 40. The above-described predetermined polishing time of the conductive film 106 and the dielectric film 103 in the third polishing unit 3C may preferably be the same as the above-described predetermined polishing time of the dielectric film 103 in the fourth polishing unit 3D.

The polishing conditions (e.g., the polishing liquid, the polishing pressure, and the rotational speed of the polishing table) of the wafer may be changed in the third polishing process and the fourth polishing process. Further, the polishing conditions may be changed in accordance with the type of film to be polished (the conductive film 106 and the dielectric film 103) while each polishing process is being performed. For example, in the third polishing process, the polishing conditions may be changed when the removal of the conductive film 106 is detected based on the film thickness signal from the eddy current film thickness sensor 60.

In another embodiment, the polishing method may include performing a water polishing process of polishing the wafer while supplying pure water onto the polishing pad 10 on the fourth polishing table 30D prior to the fourth polishing process, obtaining a film thickness signal of the dielectric film 103 to be polished by the optical film thickness sensor 40 during the water polishing process, producing a film thickness index value from the film thickness signal by the operation controller 5, calculating a target removal amount of the dielectric film 103 from the film thickness index value and a predetermined second target value of the thickness of the dielectric film 103, calculating a polishing time for achieving the target removal amount, and performing the fourth polishing process for the calculated polishing time.

In still another embodiment, the polishing method may include performing a water polishing process of polishing the wafer while supplying pure water onto the polishing pad 10 on the fourth polishing table 30D prior to the fourth polishing process, obtaining a film thickness signal of the dielectric film 103 to be polished by the optical film thickness sensor 40 during the water polishing process, producing a film thickness index value from the film thickness signal by the operation controller 5, calculating a target removal amount of the dielectric film 103 from the film thickness index value and a predetermined second target value of the thickness of the dielectric film 103, and terminating the fourth polishing process when the removal amount of the dielectric film 103 in the fourth polishing process reaches the target removal amount of the dielectric film 103.

During the water polishing process, polishing of the wafer does not substantially progress. Performing of the water polishing process can remove the polishing liquid, the polishing debris, and the by-products from the polishing pad 10, enabling the optical film thickness sensor 40 to obtain more accurate film thickness signal. Therefore, the operation controller 5 is able to detect the polishing end point more accurately. Furthermore, since the accuracy of the polishing end point detection is improved, the rework (i.e., re-polishing of the wafer) can be eliminated or the number of reworks can be reduced. Consequently, the throughput of wafer polishing can be improved.

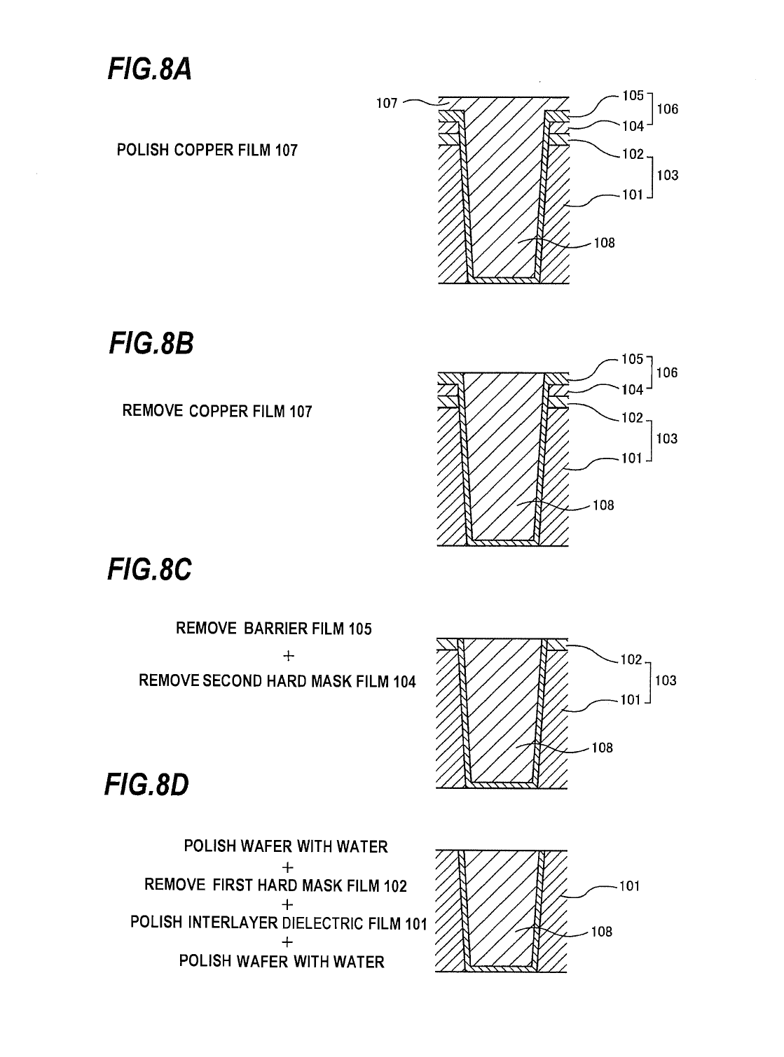

Still another embodiment of the polishing method will be described below with reference to FIGS. 8A through 8D. A first polishing process shown in FIG. 8A and a second polishing process shown in FIG. 8B are identical respectively to the first polishing process and the second polishing process according to the above-discussed embodiment shown in FIG. 5A and FIG. 5B, respectively, and their repetitive descriptions are omitted.

The wafer that has been polished in the second polishing unit 3B is transported to the third polishing unit 3C where a third polishing process is performed. In the third polishing process, as shown in FIG. 8C, the barrier film 105 and the second hard mask film 104, which constitute the conductive film 106, are removed. More specifically, the conductive film 106 is polished until the dielectric film 103 lying underneath the conductive film 106 is exposed, i.e., until the first hard mask film 102 is exposed. During polishing of the conductive film 106, the film thickness signal of the conductive film 106 is obtained by the eddy current film thickness sensor 60. The operation controller 5 produces the film thickness index value from the film thickness signal, monitors polishing of the conductive film 106 based on the film thickness index value, and terminates polishing of the wafer when the film thickness index value reaches a predetermined threshold value or when the film thickness index value stops changing, i.e., when the first hard mask film 102 is exposed as a result of removal of the second hard mask film 104 of the conductive film 106.

In the third polishing process, it is preferable to use a polishing liquid of high selectivity which contains abrasive grains and/or chemical composition capable of increasing the polishing rate of the conductive film 106 while lowering the polishing rate of the dielectric film 103. With use of such a polishing liquid, polishing of the wafer does not substantially progress after the dielectric film 103 is exposed. Therefore, the operation controller 5 is able to detect the polishing end point of the conductive film 106 more accurately, i.e., the point of time when the dielectric film 103 is exposed. Furthermore, since the accuracy of the polishing end point detection is improved, the rework (i.e., additional polishing of the wafer) can be eliminated or the number of reworks can be reduced. Consequently, a throughput of wafer polishing can be improved. In the case where such a polishing liquid of high selectivity is used in the third polishing process, the polishing end point of the conductive film 106, i.e., the point of time when the dielectric film 103 is exposed, can be detected based on the torque current of the table motor 19 which rotates the polishing table 30C.

The polished wafer is then transported from the third polishing unit 3C to the fourth polishing unit 3D where a fourth polishing process is performed. In the fourth polishing process, as shown in FIG. 8D, the dielectric film 103, which is constituted by the first hard mask film 102 and the interlayer dielectric film 101, is polished. More specifically, the fourth polishing process is carried out as follows.

Before the dielectric film 103 is polished, the wafer is water-polished with pure water supplied from the polishing liquid supply mechanism 32D to the polishing pad 10 (first water polishing process). During the first water polishing process, polishing of the wafer does not substantially progress. When the first water polishing process is being performed, the initial film thickness signal of the dielectric film 103 is obtained by the optical film thickness sensor 40. After the first water polishing process, instead of the pure water, a polishing liquid is supplied to the polishing pad 10, so that the dielectric film 103 is polished in the presence of the polishing liquid between the wafer and the polishing pad 10 (fourth polishing process). Polishing of the dielectric film 103 includes removing of the first hard mask film 102 and polishing of the interlayer dielectric film 101. The dielectric film 103 is polished until its thickness reaches a predetermined target value. The operation controller 5 may judge whether or not the thickness of the dielectric film 103 has reached the predetermined target value, based on the film thickness index value or the removal index value that has been produced from the film thickness signal obtained by the optical film thickness sensor 40, or based on whether a predetermined polishing time has elapsed or not.

After the dielectric film 103 has been polished, the wafer is water-polished with pure water supplied to the polishing pad 10 (second water polishing process). When the second water polishing process is being performed, an end-point film thickness signal of the dielectric film 103 is obtained by the optical film thickness sensor 40. The operation controller 5 calculates a removal amount of the dielectric film 103 from a difference between the initial film thickness signal and the end-point film thickness signal, and determines whether or not the thickness of the polished dielectric film 103 has reached its target value from the calculated removal amount, an initial thickness of the dielectric film 103, and the target value of the thickness of the dielectric film 103. If the thickness of the polished dielectric film 103 has not reached the target value, then the operation controller 5 calculates an additional polishing time required for the thickness of the polished dielectric film 103 to reach its target value. The additional polishing time can be calculated from a difference between the current thickness of the dielectric film 103 and the target value thereof, and the polishing rate. After the second water polishing process is finished, the polishing liquid is supplied again to the polishing pad 10, and the wafer is polished again for the additional polishing time in the fourth polishing unit 3D. According to the present embodiment, the removal amount of the dielectric film 103 can accurately be calculated from the film thickness signal that has been obtained during water-polishing of the wafer.

The optical film thickness sensor 40 may be disposed beside the polishing table 30D. In this arrangement, the wafer is moved horizontally on the polishing pad 10 by the top ring 31D until the wafer overhangs the optical film thickness sensor 40, and the optical film thickness sensor 40 obtains the film thickness signal of the dielectric film 103 of the wafer in the overhanging position.

More specifically, before the fourth polishing process, the wafer is moved horizontally on the polishing pad 10 by the top ring 31D to the overhanging position where the wafer overhangs the optical film thickness sensor 40, and the optical film thickness sensor 40 obtains an initial film thickness signal of the dielectric film 103 of the wafer in the overhanging position. The wafer is then moved back to the polishing position on the polishing pad 10 by the top ring 31D, and thereafter is polished with the polishing liquid for a predetermined polishing time (fourth polishing process). After the dielectric film 103 is polished, the wafer is moved again to the overhanging position over the optical film thickness sensor 40. In this state, an end-point film thickness signal of the dielectric film 103 is obtained by the optical film thickness sensor 40.

The operation controller 5 then calculates the removal amount of the dielectric film 103 from the difference between the initial film thickness signal and the end-point film thickness signal, and determines whether or not the thickness of the polished dielectric film 103 has reached its target value from the calculated removal amount, the initial thickness of the dielectric film 103, and the target value of the thickness of the dielectric film 103. If the thickness of the polished dielectric film 103 has not reached the target value, then the operation controller 5 calculates an additional polishing time required for the thickness of the polished dielectric film 103 to reach its target value. The wafer is moved back to the polishing position on the polishing pad 10, the polishing liquid is supplied to the polishing pad 10, and the wafer is polished again for the additional polishing time in the fourth polishing unit 3D. In this embodiment, the first water polishing process may be carried out before the initial film thickness signal is obtained, and the second water polishing process may be carried out after the fourth polishing process is performed and before the end-point film thickness signal is obtained.

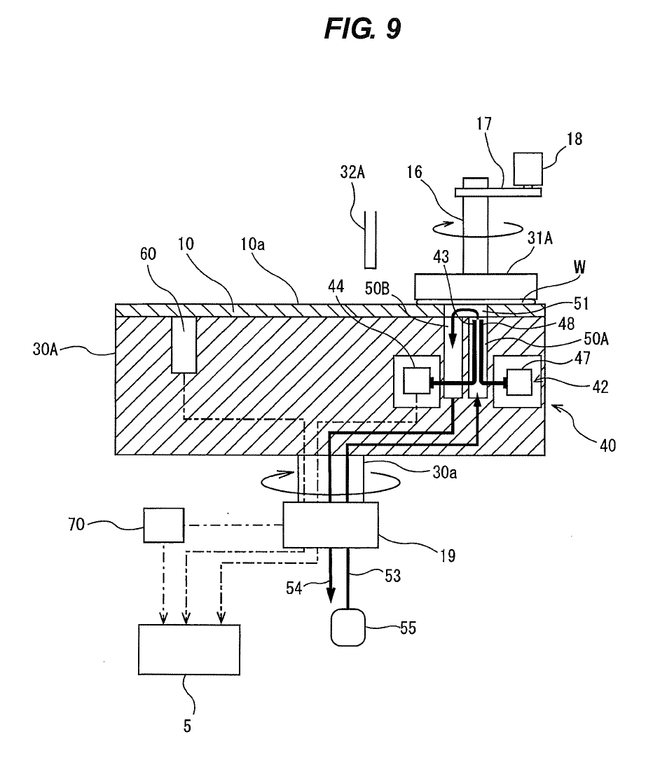

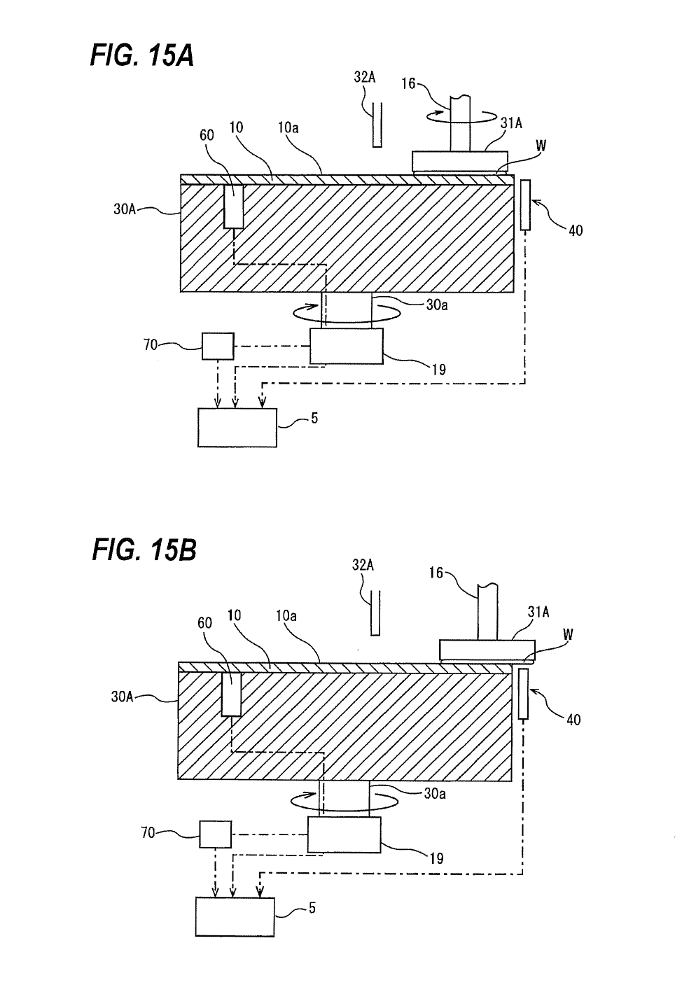

A first optical film thickness sensor may be disposed in the fourth polishing table 30D, and a second optical film thickness sensor may be disposed beside the fourth polishing table 30D. Structure and arrangement of the first optical film thickness sensor are the same as those of the optical film thickness sensor 40 shown in FIG. 9, and structure and arrangement of the second optical film thickness sensor are the same as those of the optical film thickness sensor 40 shown in FIGS. 15A and 15B. Therefore, their repetitive descriptions are omitted.

An embodiment of the polishing method using two optical film thickness sensors will be described below. Before the fourth polishing process, the wafer is moved by the top ring 31D until the wafer overhangs the second optical film thickness sensor, which obtains the initial film thickness signal of the dielectric film 103 of the wafer in the overhanging position. The wafer may be water-polished with pure water before the second optical film thickness sensor obtains the initial film thickness signal. The wafer is then moved back to the polishing position on the polishing pad 10 by the top ring 31D, and the dielectric film 103 is polished in the presence of the polishing liquid for a predetermined time (fourth polishing process). After the dielectric film 103 is polished, instead of the polishing liquid, pure water is supplied to the polishing pad 10 on the fourth polishing table 30D, and the wafer is water-polished with the pure water. When this water polishing process is being performed, the first optical film thickness sensor obtains the end-point film thickness signal of the dielectric film 103 of the wafer.

The operation controller 5 calculates the removal amount of the dielectric film 103 from the difference between the initial film thickness signal and the end-point film thickness signal, and determines whether or not the thickness of the polished dielectric film 103 has reached its target value from the calculated removal amount, the initial thickness of the dielectric film 103, and the target value of the thickness of the dielectric film 103. If the thickness of the polished dielectric film 103 has not reached the target value, then the operation controller 5 calculates an additional polishing time required for the thickness of the polished dielectric film 103 to reach its target value. The polishing liquid is supplied to the polishing pad 10 on the fourth polishing table 30D, and the wafer is polished again for the additional polishing time in the fourth polishing unit 3D.

According to each of the above embodiments, the conductive film 106 and the dielectric film 103, which have conventionally been polished with use of a single polishing table, are polished in the two polishing tables 30C and 30D. Therefore, not only the polishing time per one polishing table can be shortened, but also the difference between the polishing time at the polishing tables 30A and 30B and the polishing time at the polishing tables 30C and 30D can be reduced. Therefore, the throughput of wafer polishing can be increased. Furthermore, since the accuracy of the polishing end point detection is improved, the rework (i.e., re-polishing of the wafer) can be eliminated or the number of reworks can be reduced. Consequently, the throughput of wafer polishing can be improved. Each of the above embodiments is also applicable to polishing of a wafer having multilayer structure that does not include the first hard mask film 102 and/or the second hard mask film 104.

The wafer thus polished is cleaned and dried in the cleaning section 4, and is returned to the wafer cassette on the front load section 20 by the transfer robot 22. Thereafter, the wafer may be delivered to a film thickness measuring device provided outside of the polishing apparatus, and the film thickness of the polished dielectric film 103 may be measured by the film thickness measuring device. If the film thickness of the polished dielectric film 103 is larger than the target value thereof or the removal amount of the dielectric film 103 is smaller than the target value thereof, then the wafer is transported back into the polishing apparatus and polished again in the fourth polishing unit 3D.

Next, the eddy current film thickness sensor 40 and the optical film thickness sensor 60 provided in each of the polishing units 3A to 3D will be described. FIG. 9 is a schematic cross-sectional view showing the first polishing unit 3A having the eddy current film thickness sensor and the optical film thickness sensor. The polishing units 3B to 3D have the same structure as that of the first polishing unit 3A shown in FIG. 9 and their repetitive descriptions are omitted.

This optical film thickness sensor 40 and the optical film thickness sensor 60 are disposed in the polishing table 30A and are rotated together with the polishing table 30A. The top ring shaft 16 is coupled to a top ring motor 18 through a coupling device, such as belt, so that the top ring shaft 16 is rotated by the top ring motor 18. This rotation of the top ring shaft 16 rotates the top ring 31A in the direction as indicated by arrow.

The optical film thickness sensor 40 is configured to irradiate the surface of the wafer W with light, receive the light reflected from the wafer W, and break up the reflected light according to wavelength. The optical film thickness sensor 40 includes an irradiator 42 for irradiating the surface, to be polished, of the wafer W with the light, an optical fiber 43 as an optical receiver for receiving the reflected light from the wafer W, a spectrometer 44 configured to resolve the reflected light according to the wavelength and measure intensity of the reflected light over a predetermined wavelength range.

The polishing table 30A has a first hole 50A and a second hole 50B having upper open ends lying in the upper surface of the polishing table 30A. The polishing pad 10 has a through-hole 51 at a position corresponding to the holes 50A and 50B. The holes 50A and 50B are in fluid communication with the through-hole 51, which has an upper open end lying in the polishing surface 10a. The first hole 50A is coupled to a liquid supply source 55 via a liquid supply passage 53 and a rotary joint (not shown). The second hole 50B is coupled to a liquid discharge passage 54.

The irradiator 42 includes a light source 47 for emitting multiwavelength light and the optical fiber 48 coupled to the light source 47. The optical fiber 48 is an optical transmission element for directing the light, emitted by the light source 47, to the surface of the wafer W. The tip ends of the optical fiber 48 and the optical fiber 43 lie in the first hole 50A and are located near the surface, to be polished, of the wafer W. The tip ends of the optical fiber 48 and the optical fiber 43 are arranged so as to face the wafer W held by the top ring 31A, so that multiple zones of the wafer W are irradiated with the light each time the polishing table 30A makes one revolution. Preferably, the tip ends of the optical fiber 48 and the optical fiber 43 are arranged so as to face the center of the wafer W held by the top ring 31A.

During polishing of the wafer W, the liquid supply source 55 supplies water (preferably pure water) as a transparent liquid into the first hole 50A through the liquid supply passage 53. The water fills a space formed between the lower surface of the wafer W and the tip ends of the optical fibers 48 and 43. The water further flows into the second hole 50B and is expelled therefrom through the liquid discharge passage 54.

The polishing liquid is discharged together with the water and thus a path of light is secured. The liquid supply passage 53 is provided with a valve (not shown in the drawing) configured to operate in conjunction with the rotation of the polishing table 30A. The valve operates so as to stop the flow of the water or reduce the flow of the water when the wafer W is not located over the through-hole 51.

The optical fiber 48 and the optical fiber 43 are arranged in parallel with each other. The tip ends of the optical fiber 48 and the optical fiber 43 are substantially perpendicular to the surface of the wafer W, so that the optical fiber 48 directs the light to the surface of the wafer W substantially perpendicularly.

During polishing of the wafer W, the irradiator 42 irradiates the wafer W with the light, and the optical fiber (optical receiver) 43 receives the light reflected from the wafer W. The spectrometer 44 measures the intensity of the reflected light at each of the wavelengths over the predetermined wavelength range and sends light intensity data to the operation controller 5. This light intensity data is the film thickness signal reflecting the film thickness of the wafer W and varying in accordance with the film thickness of the wafer W. The operation controller 5 produces a spectrum showing the light intensities at the respective wavelengths from the light intensity data, and further produces the film thickness index value representing the film thickness of the wafer W from the spectrum.

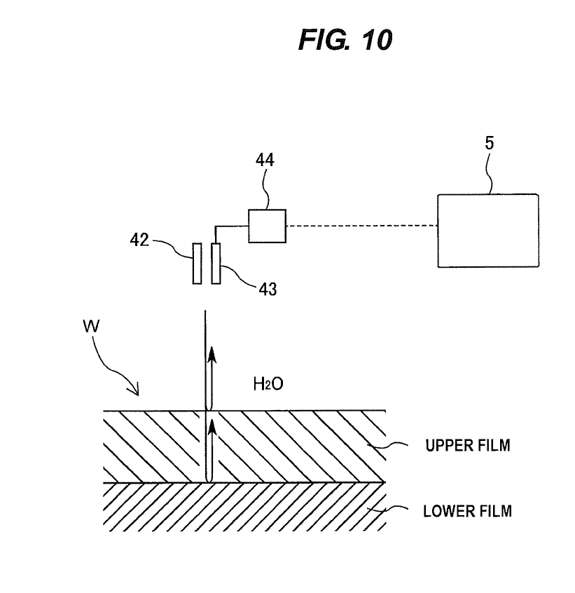

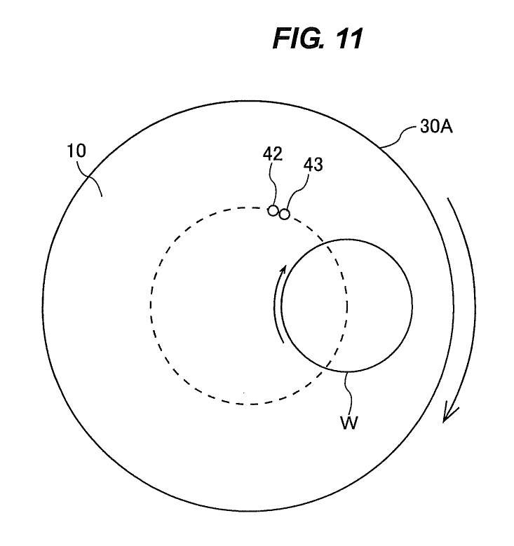

FIG. 10 is a schematic view illustrating the principle of the optical film thickness sensor 40, and FIG. 11 is a plan view showing a positional relationship between the wafer W and the polishing table 30A. In this example shown in FIG. 10, the wafer W has a lower film and an upper film formed on the lower film. The irradiator 42 and the optical receiver 43 are oriented toward the surface of the wafer W. The irradiator 42 is configured to direct the light to the multiple zones, including the center of the wafer W, on the surface of the wafer W each time the polishing table 30A makes one revolution.

The light, directed to the wafer W, is reflected off an interface between a medium (e.g., water in the example of FIG. 10) and the upper film and an interface between the upper film and the lower film. Light waves from these interfaces interfere with each other. The manner of interference between the light waves varies according to the thickness of the upper film (i.e., a length of an optical path). As a result, the spectrum, produced from the reflected light from the wafer, varies according to the thickness of the upper film. The spectrometer 44 breaks up the reflected light according to the wavelength and measures the intensity of the reflected light at each of the wavelengths. The operation controller 5 produces the spectrum from the light intensity data (the film thickness signal) obtained from the spectrometer 44. This spectrum is expressed as a line graph (i.e., a spectral waveform) indicating a relationship between the wavelength and the intensity of the light. The intensity of the light can also be expressed as a relative value, such as a reflectance or a relative reflectance.

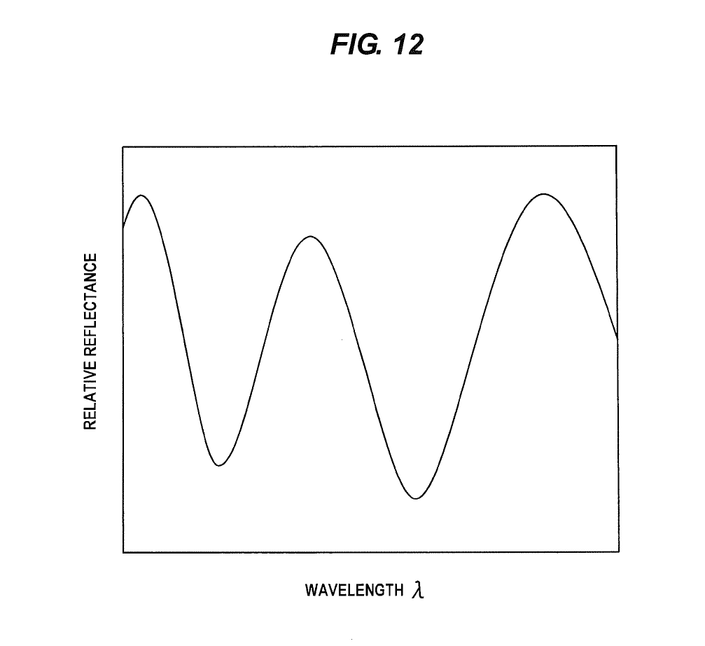

FIG. 12 is a diagram showing the spectrum created by the operation controller 5. In FIG. 12, horizontal axis represents the wavelength of the reflected light, and vertical axis represents relative reflectance derived from the intensity of the light. The relative reflectance is an index that represents the intensity of the reflected light. More specifically, the relative reflectance is a ratio of the intensity of the reflected light to a predetermined reference intensity. By dividing the intensity of the light (i.e., the actually measured intensity) by the corresponding reference intensity at each of the wavelengths, unwanted noise, such as a variation in the intensity inherent in an optical system or the light source, are removed from the actually measured intensity. As a result, the spectrum reflecting only the thickness information of the upper film can be obtained.

The predetermined reference intensity may be an intensity of the reflected light obtained when a silicon wafer (bare wafer) with no film thereon is being polished in the presence of water. In the actual polishing process, the relative reflectance is obtained as follows. A dark level (which is a background intensity obtained under the condition that the light is cut off) is subtracted from the actually measured intensity to determine a corrected actually measured intensity. Further, the dark level is subtracted from the reference intensity to determine a corrected reference intensity. Then the relative reflectance is calculated by dividing the corrected actually measured intensity by the corrected reference intensity. That is, the relative reflectance R(λ) can be calculated by using the following equation (1).

$$R ( λ ) = \frac{E ( λ ) - D ( λ )}{B ( λ ) - D ( λ )} \qquad ( 1 )$$

where λ is wavelength, E(λ) is the intensity of the reflected light at the wavelength λ, B(λ) is the reference intensity at the wavelength λ, and D(λ) is the dark level at the wavelength λ (i.e., the intensity of the light obtained under the condition that the light is cut off).

The operation controller 5 compares the spectrum, which is produced during polishing of the wafer, with a plurality of reference spectra so as to determine a reference spectrum that is most similar to the spectrum produced. A film thickness associated with the determined reference spectrum is determined to be a current film thickness by the operation controller 5. The plurality of reference spectra are those obtained in advance by polishing a wafer of the same type as the wafer to be polished. Each reference spectrum is associated with a film thickness at a point of time when that reference spectrum is obtained. Specifically, each reference spectrum is obtained at different film thickness, and the plurality of reference spectra correspond to different film thicknesses. Therefore, the current film thickness can be estimated by determining the reference spectrum that is most similar to the current spectrum. This estimated film thickness is the above-mentioned film thickness index value.

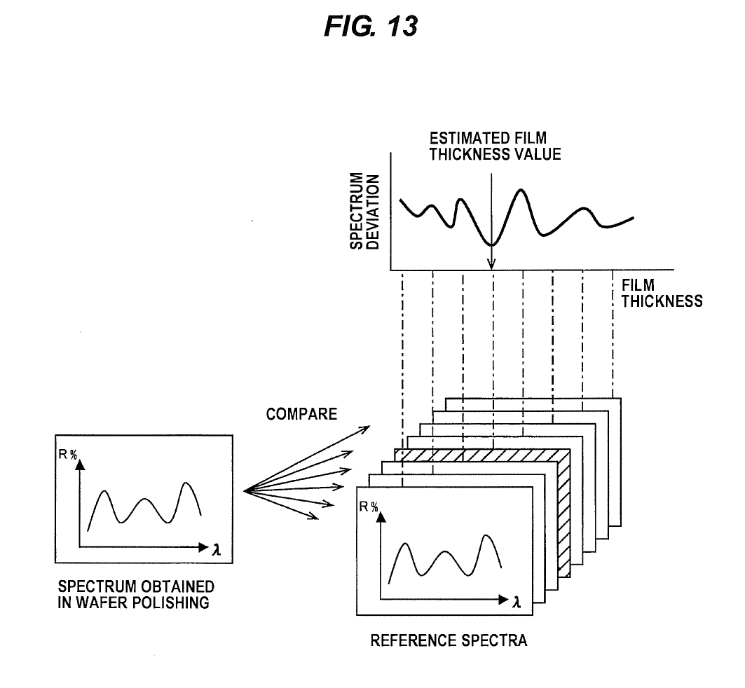

FIG. 13 is a diagram illustrating a process of determining the current film thickness from the comparison of the current spectrum created by the operation controller with the plurality of reference spectra. As shown in FIG. 13, the operation controller 5 compares the current spectrum, which is produced from the light intensity data, with the plurality of reference spectra, and determines the most similar reference spectrum. More specifically, the operation controller 5 calculates a deviation between the current spectrum and each reference spectrum, and identifies the reference spectrum with the smallest deviation as the most similar reference spectrum. The operation controller 5 determines that the current film thickness is the film thickness associated with the most similar reference spectrum identified.

The optical film thickness sensor 40 is suitable for use in determining the thickness of the dielectric film 103 which allows light to pass therethrough. The operation controller 5 may determine the removal amount of the dielectric film 103 from the film thickness index value (i.e., the light intensity data) obtained by the optical film thickness sensor 40. More specifically, an initial estimated film thickness is determined from the initial film thickness index value (i.e., initial light intensity data) in accordance with the above-described method, and the removal amount is determined by subtracting the current estimated film thickness from the initial estimated film thickness.

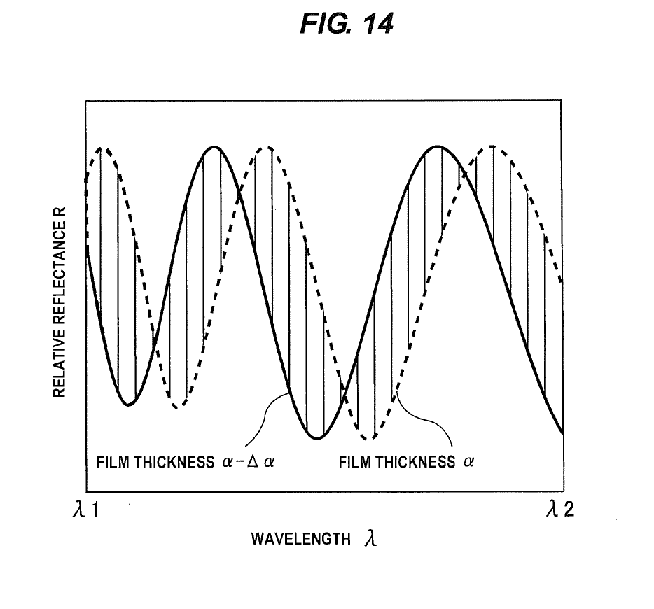

Instead of the above-described method, the removal amount of the dielectric film 103 may be determined from an amount of change in the spectrum that varies in accordance with the film thickness. FIG. 14 is a schematic view showing two spectra corresponding to a film thickness difference Δα. In FIG. 14, α represents the film thickness. This film thickness α decreases with time during polishing of the wafer (Δα>0). As shown in FIG. 14, as the film thickness changes, the spectrum moves along a wavelength axis. The amount of change between the two spectra obtained at two different times corresponds to a region (shown by hatching) surrounded by these spectra. Therefore, the removal amount of the dielectric film 103 can be determined by calculating the area of this region. The removal amount D of the dielectric film 103 is determined using the following equation (2).

$$D = {{\sum }_{λ 1}}^{λ 2} \vert Rc ( λ ) - Rp ( λ ) \vert \qquad ( 2 )$$

where λ is wavelength of the light, λ1 and λ2 are minimum wavelength and maximum wavelength that determine the wavelength range of the spectrum to be monitored, Rc is currently obtained relative reflectance, and Rp is previously obtained relative reflectance. The amount of change in the spectrum calculated by the equation (2) is the removal index value indicating the removal amount of the dielectric film 103.

As shown in FIG. 15A, the optical film thickness sensor 40 may be disposed beside the polishing table 30A. As shown in FIG. 15B, the wafer W is moved horizontally on the polishing pad 10 by the top ring 31A until the wafer W overhangs the optical film thickness sensor 40. In this state, the optical film thickness sensor 40 obtains the film thickness signal of the wafer W. Although the details of the optical film thickness sensor 40 are not shown in FIGS. 15A and 15B, the structure of the optical film thickness sensor 40 is the same as that shown in FIG. 9. The liquid supply passage 53, the liquid discharge passage 54, and the liquid supply source 55 shown in FIG. 9 are not provided in the embodiment shown in FIGS. 15A and 15B. The optical film thickness sensor 40 in this embodiment is not rotated in unison with the polishing table 30A.

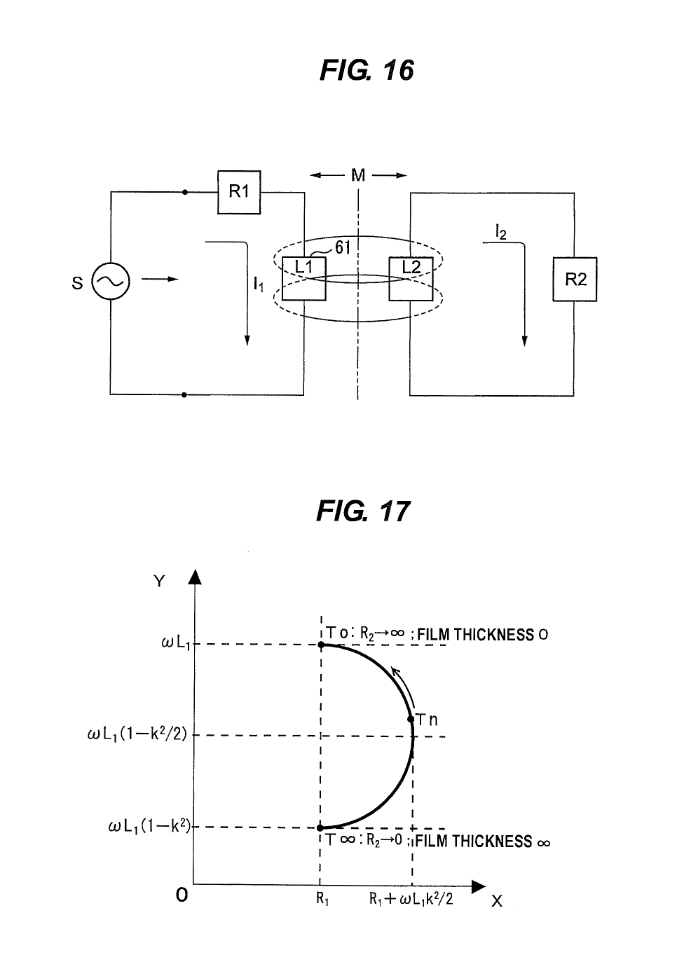

Next, the eddy current film thickness sensor 60 will be described. The eddy current film thickness sensor 60 is configured to pass a high-frequency alternating current to a coil so as to induce the eddy current in a conductive film and detect the thickness of the conductive film from the change in the impedance due to a magnetic field produced by the induced eddy current. FIG. 16 is a diagram showing a circuit for illustrating the principle of the eddy current film thickness sensor 60. When an AC power supply S (a voltage E [V]) passes a high-frequency alternating current I₁ to a coil 61, magnetic lines of force, induced in the coil 61, pass through the conductive film. As a result, mutual inductance occurs between a sensor-side circuit and a conductive-film-side circuit, and an eddy current I₂ flows in the conductive film. This eddy current I₂ generates magnetic lines of force, which cause a change in an impedance of the sensor-side circuit. The eddy current film thickness sensor 60 measures the thickness of the conductive film from the change in the impedance of the sensor-side circuit.

In the sensor-side circuit and the conductive-film-side circuit in FIG. 16, the following equations hold.

R₁I₁+L₁dI₁/dt+MdI₂/dt=E (3)

R₂I₂+L₂dI₂/dt+MdI₁/dt=0 (4)

where M represents mutual inductance, R₁ represents equivalent resistance of the sensor-side circuit including the coil Q, L₁ represents self-inductance of the sensor-side circuit including the coil Q, R₂ represents equivalent resistance of the conductive film in which the eddy current is induced, and L₂ represents self-inductance of the conductive film through which the eddy current flows.

Letting Iₙ=Aₙe^{jωt} (sine wave), the above equations (3) and (4) are expressed as follows.

(R₁+jωL₁)I₁+jωMI₂=E (5)

(R₂+jωL₂)I₂+jωMI₂=1 (6)

From these equations (5) and (6), the following equations are derived.

$${I}_{1} = E ( {R}_{2} + j ω {L}_{2} ) \\ \begin{matrix}{I}_{1} = \frac{E ( {R}_{2} + j ω {L}_{2} )}{[ ( {R}_{1} + j ω {L}_{1} ) ( {R}_{2} + j ω {L}_{2} ) + {ω}^{2} {M}^{2} ]} \\ = \frac{E}{[ ( {R}_{1} + j ω {L}_{1} ) + {ω}^{2} {M}^{2} / ( {R}_{2} + j ω {L}_{2} ) ]}\end{matrix} \qquad ( 7 )$$

Thus, the impedance Φ of the sensor-side circuit is given by the following equation.

Φ=E/I₁=[R₁+ω²M²R₂/(R₂²+ω²L₂²)]+jω[L₁−ω²L₂M²/(R₂²+ω²L₂²)] (8)

Substituting X and Y for a real part (i.e., a resistance component) and an imaginary part (i.e., an inductive reactance component) respectively, the above equation (8) is expressed as follows.

Φ=X+jωY (9)

The eddy current film thickness sensor 60 outputs the resistance component X and the inductive reactance component Y of the impedance of the electric circuit including the coil 61 of the eddy current film thickness sensor 60. These resistance component X and the inductive reactance component Y are the film thickness signal reflecting the film thickness and vary in accordance with the film thickness of the wafer.

FIG. 17 is a diagram showing a graph drawn by plotting X and Y, which change with the film thickness, on a XY coordinate system. Coordinates of a point T∞ are values of X and Y when the film thickness is infinity, i.e., R₂ is zero. Where electrical conductivity of a substrate can be neglected, coordinates of a point T0 are values of X and Y when the film thickness is zero, i.e., R₂ is infinity. A point Tn, specified by the values of X and Y, moves in a circular arc toward the point T0 as the film thickness decreases. A symbol k in FIG. 12 represents coupling coefficient, and the following relationship holds.

M=k(L₁L₂)^{1/2} (10)

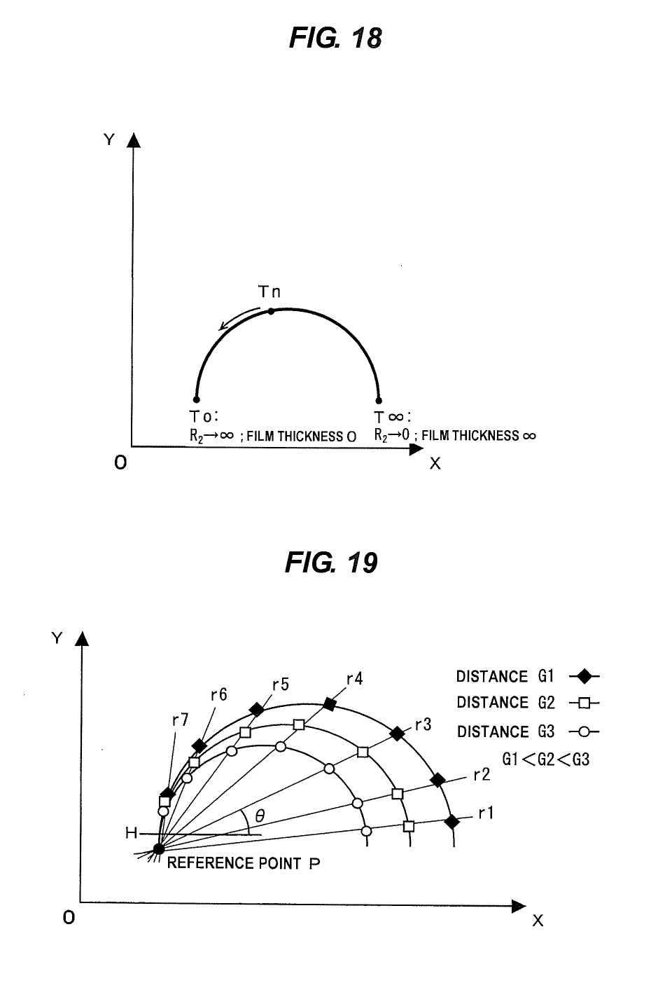

FIG. 18 shows a graph obtained by rotating the graph in FIG. 17 through 90 degrees in a counterclockwise direction and further translating the resulting graph. As shown in FIG. 18, the point Tn, which is specified by the values of X and Y, travels in a circular arc toward the point T0 as the film thickness decreases.

A distance between the coil 61 and the wafer W changes in accordance with a thickness of the polishing pad 10 that exists between the coil 61 and the wafer W. As a result, as shown in FIG. 19, the arcuate path of the coordinates X, Y changes in accordance with the distance G (G1 to G3) corresponding to the thickness of the polishing pad 10. As shown in FIG. 19, when points specified by the components X and Y at the same thickness of the conductive film are connected by lines (which will be referred to as preliminary measurement lines) with different distances G between the sensor coil 61 and the wafer W, these preliminary measurement lines (r₁, r₂, r₃, . . . ) intersect each other at an intersection (a reference point) P. Each of these preliminary measurement lines rn (n=1, 2, 3 . . . ) is inclined at an elevation angle (included angle) 0 with respect to a predetermined reference line (e.g., a horizontal line H in FIG. 19). This elevation angle θ varies depending on the thickness of the conductive film. Therefore, the angle θ is the film thickness index value indicating the film thickness of the wafer W.

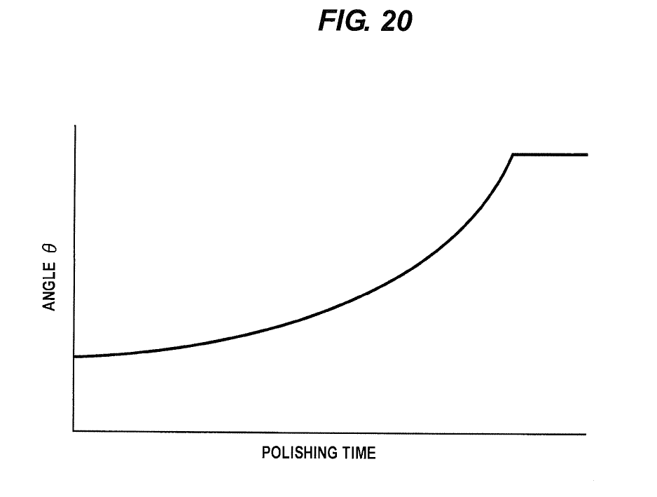

During polishing of the wafer W, the operation controller 5 can determine the film thickness from the angle θ with reference to correlation data showing a relationship between the angle θ and the film thickness. This correlation data is obtained in advance by polishing the same type of wafer as the wafer W to be polished and measuring the film thickness corresponding to each angle θ. FIG. 20 is a graph showing the angle θ that varies with the polishing time. Vertical axis represents the angle θ, and horizontal axis represents the polishing time. As shown in this graph, the angle θ increases with the polishing time, and becomes constant at a certain point of time. The operation controller calculates the angle θ during polishing and determines the current film thickness from the angle θ.

The above-described optical film thickness sensor 40 and the eddy current film thickness sensor 60 may be a known optical sensor and a known eddy current sensor as disclosed in Japanese laid-open patent publications No. 2004-154928 and No. 2009-99842.

As shown in FIG. 9, in addition to the optical film thickness sensor 40 and the eddy current film thickness sensor 60, the torque current measuring device 70 is provided for measuring the input current (i.e., the torque current) of the table motor 19 that rotates the polishing table 30A. The value of the torque current measured by the torque current measuring device 70 is sent to the operation controller 5, which monitors the value of the torque current during polishing of the wafer W. Instead of providing the torque current measuring device 70, a current value outputted from an inverter (now shown) for driving the table motor 19 may be used for monitoring the torque current.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims and equivalents.

What is claimed is:

1. A method of polishing a substrate having a dielectric film, a conductive film formed on the dielectric film, and a metal film formed on the conductive film, said method comprising:
performing a first polishing process of bringing the substrate into sliding contact with a polishing pad on a first polishing table to polish the metal film;
performing a second polishing process of bringing the substrate into sliding contact with a polishing pad on a second polishing table to polish the metal film until the conductive film is exposed;
performing a third polishing process of bringing the substrate into sliding contact with a polishing pad on a third polishing table to polish at least the conductive film; and
performing a fourth polishing process of bringing the substrate into sliding contact with a polishing pad on a fourth polishing table to polish at least the dielectric film.

2. The method according to claim 1, wherein a first processing time which is a sum of a polishing time of the first polishing process and a time of a first preparing process performed before and/or after the first polishing process is equal to a second processing time which is a sum of a polishing time of the second polishing process and a time of a second preparing process performed before and/or after the second polishing process.

3. The method according to claim 2, wherein each of the first preparing process and the second preparing process includes at least one of a transporting process of the substrate, a dressing process of the polishing pad, and a water-polishing process in which the substrate is polished while water is supplied onto the polishing pad.

4. The method according to claim 1, wherein:
the third polishing process comprises a process of bringing the substrate into sliding contact with the polishing pad on the third polishing table to polish the conductive film until a thickness of the conductive film reaches a predetermined target value; and
the fourth polishing process comprises a process of bringing the substrate into sliding contact with the polishing pad on the fourth polishing table to polish the conductive film until the dielectric film is exposed and further polish the dielectric film until a thickness of the dielectric film reaches a predetermined target value.

5. The method according to claim 4, wherein the third polishing process is performed for a predetermined polishing time and the fourth polishing process is performed for a predetermined polishing time.

6. The method according to claim 5, wherein the predetermined polishing time of the third polishing process is equal to the predetermined polishing time of the fourth polishing process.

7. The method according to claim 4, wherein a polishing end point of at least one of the third polishing process and the fourth polishing process is detected with use of a film thickness sensor disposed in the third polishing table and/or the fourth polishing table.

8. The method according to claim 4, wherein a polishing end point of the third polishing process is determined based on a film thickness signal from an eddy current film thickness sensor disposed in the third polishing table.

9. The method according to claim 4, wherein a polishing end point of the fourth polishing process is determined based on a film thickness signal from an optical film thickness sensor disposed in the fourth polishing table.

10. The method according to claim 4, wherein a third processing time which is a sum of a polishing time of the third polishing process and a time of a third preparing process performed before and/or after the third polishing process is equal to a fourth processing time which is a sum of a polishing time of the fourth polishing process and a time of a fourth preparing process performed before and/or after the fourth polishing process.

11. The method according to claim 10, wherein the predetermined target value of the thickness of the conductive film is adjusted such that the third processing time is equal to the fourth processing time.

12. The method according to claim 10, wherein each of the third preparing process and the fourth preparing process includes at least one of a transporting process of the substrate, a dressing process of the polishing pad, and a water-polishing process in which the substrate is polished while water is supplied onto the polishing pad.

13. The method according to claim 1, wherein:
the third polishing process comprises a process of bringing the substrate into sliding contact with the polishing pad on the third polishing table to polish the conductive film until the dielectric film is exposed; and
the fourth polishing process comprises a process of bringing the substrate into sliding contact with the polishing pad on the fourth polishing table to polish the dielectric film until a thickness of the dielectric film reaches a predetermined target value.

14. The method according to claim 13, wherein the third polishing process is performed while supplying a polishing liquid onto the polishing pad on the third polishing table, the polishing liquid having properties capable of increasing a polishing rate of the conductive film and lowering a polishing rate of the dielectric film.

15. The method according to claim 13, wherein a polishing end point of at least one of the third polishing process and the fourth polishing process is detected with use of a film thickness sensor disposed in the third polishing table and/or the fourth polishing table.

16. The method according to claim 13, wherein a polishing end point of the third polishing process is determined based on a film thickness signal from an eddy current film thickness sensor disposed in the third polishing table.

17. The method according to claim 13, wherein a polishing end point of the fourth polishing process is determined based on a film thickness signal from an optical film thickness sensor disposed in the fourth polishing table.

18. The method according to claim 14, wherein a polishing end point of the third polishing process is determined based on a change in torque current of a table motor for rotating the third polishing table.

19. The method according to claim 13, further comprising:
prior to the fourth polishing process, performing a water polishing process of polishing the substrate while supplying water onto the polishing pad on the fourth polishing table;
obtaining an initial film thickness signal of the dielectric film when the water polishing process is performed;
producing an initial film thickness index value from the initial film thickness signal;
calculating a target removal amount of the dielectric film from the initial film thickness index value and the predetermined target value of the thickness of the dielectric film; and
terminating the fourth polishing process when a removal amount of the dielectric film has reached the target removal amount.

20. The method according to claim 13, further comprising:
prior to the fourth polishing process, performing a first water polishing process of polishing the substrate while supplying water onto the polishing pad on the fourth polishing table;
obtaining an initial film thickness signal of the dielectric film by an optical film thickness sensor disposed in the fourth polishing table when the first water polishing process is performed;
after the fourth polishing process, performing a second water polishing process of polishing the substrate while supplying water onto the polishing pad on the fourth polishing table;
obtaining an end point film thickness signal of the dielectric film by the optical film thickness sensor when the second water polishing process is performed;
calculating a removal amount of the dielectric film from a difference between the initial film thickness signal and the end point film thickness signal; and
determining whether or not the thickness of the dielectric film has reached the predetermined target value, based on the calculated removal amount, an initial thickness of the dielectric film, and the predetermined target value of the thickness of the dielectric film.

21. The method according to claim 20, further comprising:
if the thickness of the dielectric film has not reached the predetermined target value, calculating an additional polishing time for achieving the predetermined target value; and
polishing the substrate again for the additional polishing time while supplying a polishing liquid onto the polishing pad.

22. The method according to claim 13, further comprising:
prior to the fourth polishing process, obtaining an initial film thickness signal of the dielectric film by an optical film thickness sensor disposed beside the fourth polishing table;
after the fourth polishing process, obtaining an end point film thickness signal of the dielectric film by the optical film thickness sensor,
calculating a removal amount of the dielectric film from a difference between the initial film thickness signal and the end point film thickness signal; and
determining whether or not the thickness of the dielectric film has reached the predetermined target value, based on the calculated removal amount, an initial thickness of the dielectric film, and the predetermined target value of the thickness of the dielectric film.

23. The method according to claim 22, further comprising:
if the thickness of the dielectric film has not reached the predetermined target value, calculating an additional polishing time for achieving the predetermined target value; and
polishing the substrate again for the additional polishing time by bringing the substrate into sliding contact with the polishing pad on the fourth polishing table.

24. The method according to claim 13, further comprising:
prior to the fourth polishing process, obtaining an initial film thickness signal of the dielectric film by a first optical film thickness sensor disposed beside the fourth polishing table;
after the fourth polishing process, performing a water polishing process of polishing the substrate while supplying water onto the polishing pad on the fourth polishing table;
when performing the water polishing process, obtaining an end point film thickness signal of the dielectric film by a second optical film thickness sensor disposed in the fourth polishing table;
calculating a removal amount of the dielectric film from a difference between the initial film thickness signal and the end point film thickness signal; and
determining whether or not the thickness of the dielectric film has reached the predetermined target value, based on the calculated removal amount, an initial thickness of the dielectric film, and the predetermined target value of the thickness of the dielectric film.

25. The method according to claim 24, further comprising:
if the thickness of the dielectric film has not reached the predetermined target value, calculating an additional polishing time for achieving the predetermined target value; and
polishing the substrate again for the additional polishing time while supplying a polishing liquid onto the polishing pad.

26. The method according to claim 1, wherein:
the third polishing process comprises a process of bringing the substrate into sliding contact with the polishing pad on the third polishing table to polish the conductive film until the dielectric film is exposed and further polish the dielectric film until a thickness of the dielectric film reaches a predetermined first target value; and
the fourth polishing process comprises a process of bringing the substrate into sliding contact with the polishing pad on the fourth polishing table to polish the dielectric film until the thickness of the dielectric film reaches a predetermined second target value.

27. The method according to claim 26, further comprising:
prior to the fourth polishing process, performing a water polishing process of polishing the substrate while supplying water onto the polishing pad on the fourth polishing table;
obtaining a film thickness signal of the dielectric film to be polished when the water polishing process is performed;
producing a film thickness index value from the film thickness signal;
calculating a target removal amount of the dielectric film from the film thickness index value and the predetermined second target value of the thickness of the dielectric film;
calculating a polishing time for achieving the target removal amount; and
performing the fourth polishing process for the calculated polishing time.

28. The method according to claim 26, further comprising:
prior to the fourth polishing process, performing a water polishing process of polishing the substrate while supplying water onto the polishing pad on the fourth polishing table;
obtaining a film thickness signal of the dielectric film to be polished when the water polishing process is performed;
producing a film thickness index value from the film thickness signal;
calculating a target removal amount of the dielectric film from the film thickness index value and the predetermined second target value of the thickness of the dielectric film; and
terminating the fourth polishing process when a removal amount of the dielectric film has reached the target removal amount.

29. The method according to claim 26, wherein the third polishing process is performed for a predetermined polishing time and the fourth polishing process is performed for a predetermined polishing time.

30. The method according to claim 29, wherein the predetermined polishing time of the third polishing process is equal to the predetermined polishing time of the fourth polishing process.

31. The method according to claim 26, wherein a polishing end point of at least one of the third polishing process and the fourth polishing process is detected with use of a film thickness sensor disposed in the third polishing table and/or the fourth polishing table.

32. The method according to claim 26, wherein a point of time when the dielectric film is exposed in the third polishing process is determined based on a film thickness signal from an eddy current film thickness sensor disposed in the third polishing table.

33. The method according to claim 26, wherein a polishing end point of the third polishing process is determined based on a film thickness signal from an optical film thickness sensor disposed in the third polishing table.

34. The method according to claim 26, wherein a point of time when the dielectric film is exposed in the third polishing process is determined based on a film thickness signal from an eddy current film thickness sensor disposed in the third polishing table, and a polishing end point of the third polishing process is determined based on a film thickness signal from an optical film thickness sensor disposed in the third polishing table.

35. The method according to claim 26, wherein a polishing end point of the fourth polishing process is determined based on a film thickness signal from an optical film thickness sensor disposed in the fourth polishing table.

36. A method of polishing a substrate having a dielectric film, a conductive film formed on the dielectric film, and a metal film formed on the conductive film, said method comprising:
performing a first polishing process of bringing the substrate into sliding contact with a polishing pad on a first polishing table to polish the metal film until a thickness of the metal film reaches a predetermined target value; and
performing a second polishing process of bringing the substrate into sliding contact with a polishing pad on a second polishing table to polish the metal film until the conductive film is exposed,
a first processing time which is a sum of a polishing time of the first polishing process and a time of a first preparing process performed before and/or after the first polishing process being equal to a second processing time which is a sum of a polishing time of the second polishing process and a time of a second preparing process performed before and/or after the second polishing process.

37. The method according to claim 36, wherein each of the first preparing process and the second preparing process includes at least one of a transporting process of the substrate, a dressing process of the polishing pad, and a water-polishing process in which the substrate is polished while water is supplied onto the polishing pad.

38. A method of polishing a substrate having a dielectric film, a conductive film formed on the dielectric film, and a metal film formed on the conductive film, said method comprising:
bringing the substrate into sliding contact with a polishing pad attached to one of two polishing tables to polish at least the conductive film, and
bringing the substrate into sliding contact with a polishing pad attached to the other of the two polishing tables to polish at least the dielectric film.
